(19) United States
(12) Patent Application Publication
(10) Pub. No.: US 2017/0365631 A1
(43) Pub. Date: Dec. 21, 2017

(54) SEMICONDUCTOR DEVICE AND METHOD OF MANUFACTURING SAME

(71) Applicant: RENESAS ELECTRONICS CORPORATION, Tokyo (JP)

(72) Inventors: Koji IIZUKA, Ibaraki (JP); Hidenori SATO, Ibaraki (JP)

(21) Appl. No.: 15/624,357

(22) Filed: Jun. 15, 2017

(30) Foreign Application Priority Data
Jun. 16, 2016 (JP) 2016-119553

(51) Int. Cl. H01L 27/146

(52) U.S. Cl. CPC H01L 27/1463; H01L 27/14687; H01L 27/14612; H01L 27/14636; H01L 27/14627

(57) ABSTRACT

To provide a solid state image sensor having improved sensitivity and at the same time, causing less dark current, noise, and the like. In a solid state image sensor having a substrate comprised of an N type semiconductor substrate and a P type epitaxial layer thereon, formed are a trench penetrating the epitaxial layer in an isolation region between a pixel region having therein array of pixels and a peripheral circuit region around the pixel region; and a DTI structure comprised of an insulating film with which the trench is filled. Transfer of electrons in the substrate between the pixel region and the peripheral circuit region is thereby prevented.

### CROSS-REFERENCE TO RELATED APPLICATIONS

The disclosure of Japanese Patent Application No. 2016-119553 filed on Jun. 16, 2016 including the specification, drawings, and abstract is incorporated herein by reference in its entirety.

### BACKGROUND

The present invention relates to a semiconductor device and a method of manufacturing same, in particular, a technology effective when applied to a semiconductor device having a solid state image sensor.

It is known that as a solid state image sensor (picture element) to be used in digital cameras and the like, a photodiode, a kind of a photodetector, is provided in the main surface of a semiconductor substrate.

In addition, as a structure that isolates elements formed in the main surface of a semiconductor substrate from each other, there is known an element isolation (deep trench isolation: DTI) structure formed by filling a high-aspect-ratio trench formed in the main surface of the semiconductor substrate with an insulating film.

Patent Document 1 (Japanese Unexamined Patent Application Publication No. Hei7(1995)-273364) describes that in a solid state image sensor, a substrate is implanted with boron at high energy for the purpose of increasing sensitivity to near infrared light and reduction in substrate voltage.

Patent Document 2 (Japanese Unexamined Patent Application Publication No. 2002-57318) describes that in a solid state image sensor, a p type impurity is introduced into an inner portion of a semiconductor substrate around a trench filled with an element isolation layer.

Patent Document 3 (Japanese Unexamined Patent Application Publication No. 2011-66067) describes that a DTI structure is provided to increase the breakdown voltage of a high breakdown voltage element.

### PATENT DOCUMENTS

[Patent Document 1] Japanese Unexamined Patent Application Publication No. Hei7(1995)-273364

### [Patent Document 2] Japanese Unexamined Patent Application Publication No. 2002-57318

### [Patent Document 3] Japanese Unexamined Patent Application Publication No. 2011-66067

### SUMMARY

There is a demand for image sensors having high sensitivity performance, but enhancement in sensitivity of pixels is accompanied with occurrence of noise and dark current in the pixels. Such problems become particularly marked in image sensors that receive near infrared light and convert it into an electric signal.

Another object and novel features will be apparent from the description herein and accompanying drawings.

Typical embodiments disclosed herein will next be outlined briefly.

In one embodiment, there is provided a semiconductor device having an N type substrate, a P type epitaxial layer on the N type substrate, a plurality of photodiodes in the upper surface of the epitaxial layer in a pixel region, and an isolation portion penetrating the P type epitaxial layer between the pixel region and a peripheral region.

In another embodiment, there is provided a method of manufacturing a semiconductor device including the following steps: providing a semiconductor substrate having an N type substrate and a P type epitaxial layer on the N type substrate, forming a plurality of photodiodes in the upper surface of the P type epitaxial layer in a pixel region, and forming an isolation portion penetrating the P type epitaxial layer between the pixel region and a peripheral region.

According to the one embodiment disclosed herein, a semiconductor device having improved performance can be provided. In particular, an image sensor having high sensitivity while preventing generation of a dark current and noise can be realized.

### BRIEF DESCRIPTION OF THE DRAWINGS

FIG. 1 is a plan view showing a semiconductor device of First Embodiment of the invention;

FIG. 2 is a cross-sectional view taken along the line A-A of FIG. 1;

FIG. 3 is a cross-sectional view describing a manufacturing step of the semiconductor device of First Embodiment of the invention;

FIG. 4 is a cross-sectional view describing a manufacturing step of the semiconductor device following that of FIG. 3;

FIG. 5 is a cross-sectional view describing a manufacturing step of the semiconductor device following that of FIG. 4;

FIG. 6 is a cross-sectional view describing a manufacturing step of the semiconductor device following that of FIG. 5;

FIG. 7 is a cross-sectional view describing a manufacturing step of the semiconductor device following that of FIG. 6;

FIG. 8 is a cross-sectional view describing a manufacturing step of the semiconductor device following that of FIG. 7;

FIG. 9 is a cross-sectional view describing a manufacturing step of the semiconductor device following that of FIG. 8;

FIG. 10 is a plan view describing a semiconductor device which is a modification example of First Embodiment of the invention;

FIG. 11 is a cross-sectional view describing a manufacturing step of a semiconductor device of Second Embodiment of the invention;

FIG. 12 is a cross-sectional view describing a manufacturing step of the semiconductor device following that of FIG. 11;

FIG. 13 is a cross-sectional view describing a manufacturing step of a semiconductor device of Modification Example 1 of Second Embodiment of the invention;

FIG. 14 is a cross-sectional view describing a manufacturing step of the semiconductor device following that of FIG. 13;

FIG. 15 is a cross-sectional view describing a manufacturing step of a semiconductor device of Modification Example 2 of Second Embodiment of the invention;

FIG. 16 is a cross-sectional view describing a manufacturing step of the semiconductor device following that of FIG. 15;

FIG. 17 is a cross-sectional view describing a manufacturing step of a semiconductor device of Modification Example 3 of Second Embodiment of the invention;

FIG. 18 is a cross-sectional view describing a manufacturing step of the semiconductor device following that of FIG. 17;

FIG. 19 is a cross-sectional view describing a manufacturing step of the semiconductor device following that of FIG. 18;

FIG. 20 is a cross-sectional view describing a manufacturing step of the semiconductor device following that of FIG. 19;

FIG. 21 is a cross-sectional view describing a manufacturing step of a semiconductor device of Third Embodiment of the invention;

FIG. 22 is a cross-sectional view describing a manufacturing step of the semiconductor device following that of FIG. 21;

FIG. 23 is a plan view describing a manufacturing step of the semiconductor device of Third Embodiment of the invention;

FIG. 24 is a cross-sectional view taken along the line B-B of FIG. 23;

FIG. 25 is a cross-sectional view taken along the line C-C of FIG. 23;

FIG. 26 is a cross-sectional view describing a manufacturing step of the semiconductor device following that of FIG. 23;

FIG. 27 is a plan view describing a semiconductor device of Modification Example 1 of Third Embodiment of the invention;

FIG. 28 is a cross-sectional view taken along the line D-D of FIG. 27;

FIG. 29 is a cross-sectional view describing a manufacturing step of a semiconductor device of Modification Example 2 of Third Embodiment of the invention;

FIG. 30 is a cross-sectional view describing a manufacturing step of the semiconductor device following that of FIG. 29;

FIG. 31 is a cross-sectional view describing a manufacturing step of the semiconductor device following that of FIG. 30;

FIG. 32 is a cross-sectional view describing a manufacturing step of a semiconductor device of Modification Example 3 of Third Embodiment of the invention;

FIG. 33 is a cross-sectional view describing a manufacturing step of the semiconductor device following that of FIG. 32; and

FIG. 34 is a cross-sectional view describing a semiconductor device of Comparative Example.

### DETAILED DESCRIPTION

Embodiments of the invention will next be described in detail based on some drawings. In all the drawings for describing the embodiments, members having the same function are identified by the same reference numeral and overlapping descriptions are omitted. In the following embodiments, a description of the same or similar portions is not repeated in principle unless particularly necessary.

A solid state image sensor on which light is incident from the upper surface side thereof will hereinafter be described as an example, but a BSI (back side illumination) type solid state image sensor can also produce an advantage similar to that of the following embodiments if a similar structure or similar process flow is employed.

The signs [−] and [+] stand for relative concentrations of an N conductivity type or P conductivity type impurity. For example, in the case of an N type impurity, the impurity concentration is higher in the order of [N⁻], [N], and [N⁺].

### First Embodiment

### <Structure of Semiconductor Device>

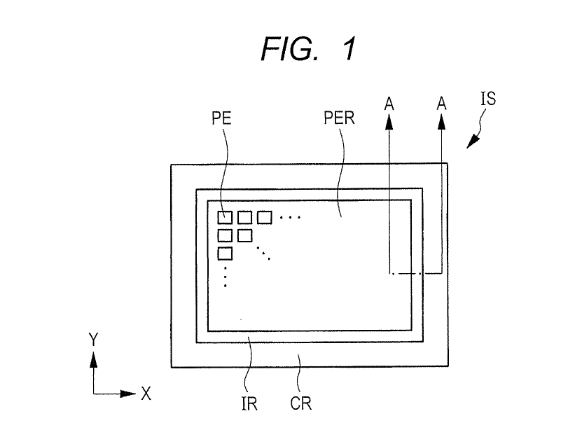

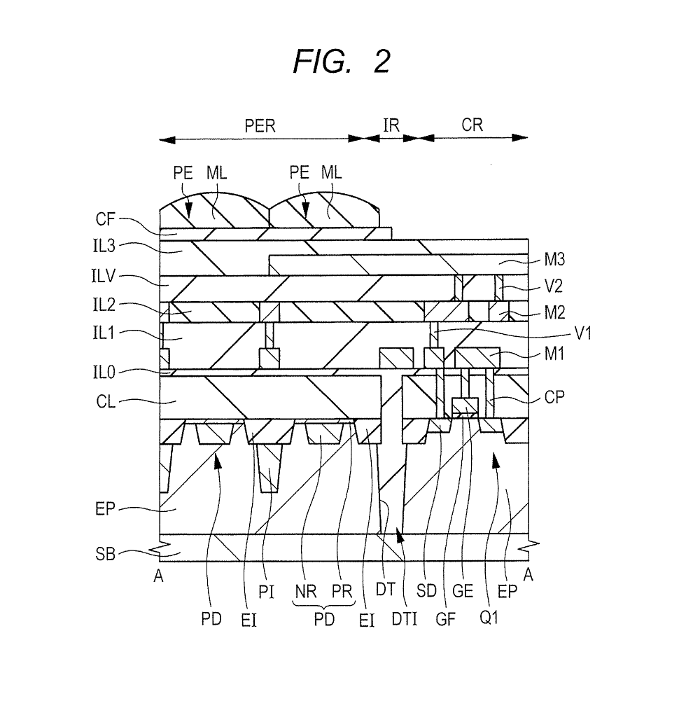

The structure of a semiconductor device of First Embodiment will hereinafter be described referring to FIGS. 1 and 2. FIG. 1 is a plan view showing the configuration of the semiconductor device of the present embodiment. FIG. 2 is a cross-sectional view showing the semiconductor device of the present embodiment. In FIG. 1, a planar structure of the entirety of a solid state image sensor (semiconductor chip) is shown schematically. FIG. 2 is a cross-sectional view taken along the line A-A of FIG. 1.

Here, a description is made with a four transistor type pixel to be used as a pixel achievement circuit in a CMOS image sensor as one example of a pixel, but the pixel is not limited thereto. Described specifically, each pixel has, around a light receiving region equipped with one photodiode, a transfer transistor and three transistors which are peripheral transistors. The peripheral transistors are a reset transistor, an amplifier transistor, and a selection transistor. Each pixel may have a plurality of photodiodes.

A solid state image sensor, which is the semiconductor device of the present embodiment, is a CMOS (complementary metal oxide semiconductor) image sensor. It is an element that receives mainly near infrared light (near infrared rays: NIR) and carries out image sensing. The wavelength of near infrared light (near infrared rays) is, for example, from 800 to 1000 nm. A solid state image sensor IS has, as shown in FIG. 1, a pixel region (pixel array region) PER and a peripheral circuit region CR that surrounds the pixel region PE in plan view. The solid state image sensor IS has, in plan view, an isolation region IR at a position around the pixel region PER and inside the closed peripheral circuit region CR. In other words, in plan view, the pixel region PER and the peripheral circuit region CR have therebetween the isolation region IR.

The pixel region PER has therein a plurality of pixels PE arranged in matrix form. More specifically, a semiconductor substrate configuring the solid state image sensor IS has, on the upper surface thereof, an array of plurality of pixels PE extending in an X direction and a Y direction along the main surface of the semiconductor substrate configuring the solid state image sensor IS. The X direction shown in FIG. 1 is a direction along a row direction along which pixels PE are arranged. The Y direction orthogonal to the X direction is a direction along a column direction along which pixels PE are arranged. The X direction is orthogonal to the Y direction.

In plan view, most of the area of each pixel PE shown in FIG. 1 is occupied by a photodiode which is a light receiving portion (photodetector). The pixel region PER, the pixel PE, and the photodiode each have a rectangular shape in plan view.

The peripheral circuit region CR is equipped with a pixel readout circuit, an output circuit, a row selection circuit, and a control circuit.

In the present application, a semiconductor substrate and an epitaxial layer (epitaxial growth layer, semiconductor layer) formed on the semiconductor substrate may be called “a substrate” or “a semiconductor substrate”, collectively. The semiconductor substrate including the epitaxial layer has, in the surface thereof, the photodiode. Source and drain regions and a channel of a field effect transistor configuring each of the above-described various circuits are present in the upper surface of the semiconductor substrate including the epitaxial layer.

The pixels PE each generate a signal based on the intensity of irradiated light. The row selection circuit selects a plurality of pixels PE in unit of row. The pixel PE selected by the row selection circuit outputs a signal thus generated to an output line. The readout circuit reads out the signal output from the pixel PE and outputs it to an output circuit.

The readout circuit reads a signal of the pixels PE. The output circuit outputs the signal of the pixel PE read by the readout circuit to the outside of the solid state image sensor IS. The control circuit totally manages the operation of the whole solid state image sensor IS and controls the operation of the other configuration elements of the solid state image sensor IS.

FIG. 2 shows a cross-section including an isolation region IR and a pixel region PER and a peripheral circuit region CR having therebetween the isolation region IR in the direction X (refer to FIG. 1). The pixel region PER in FIG. 2 has two pixels PE arranged at the end portion of the pixel region PER in the direction X. The peripheral region shown in FIG. 2 includes, for example, a transistor (field effect transistor) Q1 configuring any of the above-described pixel readout circuit, output circuit, row selection circuit, and control circuit. The isolation region IR isolates between the pixel region PER and the peripheral circuit region CR and it has a DTI structure DTI for preventing transfer of electrons and light between the pixel region PER and the peripheral circuit region CR.

As shown in FIG. 2, the solid state image sensor has an N⁻ type semiconductor substrate SB and a P type epitaxial layer (semiconductor layer) EP formed on the semiconductor substrate while being in contact with the upper surface of the semiconductor substrate SB. The thickness of the semiconductor substrate SB, that is, a distance between the main surface of the semiconductor substrate SB and the back surface, which is on the side opposite to the main surface, is, for example, 600 μm or more. The thickness of the semiconductor substrate SB here is, for example, 700 μm.

The concentration of an N type impurity (for example, P (phosphorus) or As (arsenic) of the semiconductor substrate SB is, for example, less than 1×10¹⁶ atm/cm³, more specifically, for example, about 1×10¹⁵ atm/cm³. The thickness of the epitaxial layer EP is, for example, more than 5 μm but not more than 10 μm. The concentration of a P type impurity (for example, B (boron)) of the epitaxial layer EP is, for example, from about 1×10¹⁶ to 1×10¹⁷ atm/cm³. The resistivity of the semiconductor substrate SB is, for example, from about 1 to 20 Ωcm, while that of the epitaxial layer EP is, for example, from about 1 to 20 Ωcm.

In the pixel region PER and the peripheral circuit region CR, the epitaxial layer EP has, in the upper surface thereof, an element isolation region (element isolation portion, element isolation film) EI for isolating between elements. The element isolation region EI is comprised of an insulating film such as silicon oxide film that has filled a trench formed in the upper surface of the epitaxial layer. In the pixel region PER, the epitaxial layer EP between two pixels PE adjacent to each other has, in the upper surface thereof, the element isolation region EI and the epitaxial layer EP in a region (active region) exposed from the element isolation region EI has, in the upper surface thereof, a photodiode PD. The element isolation region EI has an STI (shallow trench isolation) structure but it may have a LOCOS (local oxidation of silicon) structure instead.

The photodiode PD is comprised of a P⁺ type semiconductor region PR formed in the upper surface of the epitaxial layer EP and an N type semiconductor region NR formed in the epitaxial layer EP below the P⁺ type semiconductor region PR, while being contiguous to the bottom surface of the P⁺ type semiconductor region PR. This means that the photodiode PD is comprised of a PN junction between the P⁺ type semiconductor region PR and the N type semiconductor region NR. The concentration of an N type impurity (for example, P (phosphorus) or As (arsenic)) of the N type semiconductor region NR is, for example, from about 1×10¹⁶ to 1×10¹⁷ atm/cm³. This means that the N type semiconductor region NR has an impurity concentration higher than that of the semiconductor substrate SB.

The epitaxial layer EP just below the element isolation region EI between two pixel regions adjacent to each other has therein a P⁺ type semiconductor region PI extending from the upper surface of the epitaxial layer EP contiguous to the bottom surface of the element isolation region EI to an intermediate depth position of the epitaxial layer EP. The P⁺ type semiconductor region PI has a role of preventing electrons from transferring between pixels PE adjacent to each other. Described specifically, the P⁺ type semiconductor region PI, which is an isolation region, is a semiconductor region provided in order to prevent electrons, which are generated by photoelectric conversion of light incident on the N type semiconductor region NR and the epitaxial layer EP at a position deeper than the N type semiconductor region NR, from traveling to not the N type semiconductor region NR closest thereto but the N type semiconductor region NR of another pixel PE and being accumulated therein.

Although not shown here, each pixel PE has therein, as well as the photodiode PD, a transfer transistor formed in the upper portion of the epitaxial layer, and peripheral transistors, that is, a reset transistor, an amplifier transistor, and a selection transistor. The N type semiconductor region NR of the photodiode PD configures a source region of the transfer transistor. When image sensing is performed using a solid state image sensor, a charge is generated as a signal in the photodiode PD that has received light such as near infrared light and the transfer transistor transfers the charge to a floating diffusion region coupled to a drain region of the transfer transistor. This signal is amplified by the amplifier transistor and the selection transistor and output to the output line. In such a manner, the signal obtained by image sensing can be read out. The reset transistor is used for resetting charges accumulated in the floating diffusion region.

In the peripheral circuit region CR, the epitaxial layer EP has a transistor Q1 having a channel region in the upper surface of the epitaxial layer. The transistor Q1 described here is an N channel MISFET (metal insulator semiconductor field effect transistor), but the transistor Q1 may be a p channel MISFET. The transistor Q1 has, in an active region defined by the element isolation region EI, a gate electrode GE formed on the upper surface of the epitaxial layer EP via a gate insulating film GF. The gate electrode GE has, in the upper surface of the epitaxial layer EP beside the gate electrode GE, source and drain regions SD that sandwich the gate electrode GE therebetween in plan view. The transistor Q1 is comprised of the gate electrode GE and the source and drain regions SD.

The gate insulating film GF is made of, for example, a silicon oxide film and the gate electrode GE is made of, for example, a polysilicon film. The source and drain regions SD is comprised of an N type semiconductor region obtained by introducing an N type impurity (for example, P (phosphorus) or As (arsenic)) into the upper surface of the epitaxial layer EP. With the operation of the transistor Q1, a channel is formed in the upper surface of the epitaxial layer EP between the source and drain regions SD. Although not shown here, the source and drain regions SD and the gate electrode GE each have an upper surface covered with a silicide layer made of CoSi (cobalt silicide) or the like.

The epitaxial layer EP has thereon an interlayer insulating film CL, which covers the element isolation region EI, photodiode PD, and transistor Q1 therewith. The interlayer insulating film CL is a film stack of a plurality of insulating films. For example, the interlayer insulating film CL has a liner film (etching stopper film) made of a silicon nitride film deposited on the epitaxial layer EP and a silicon oxide film deposited on the liner film. The interlayer insulating film CL has a planarized upper surface.

The semiconductor substrate SB in the isolation region IR has therein a trench DT extending from the upper surface to the lower surface of the epitaxial layer EP. The trench DT is opened at the lower surface of the element isolation region EI. The formation range of the trench DT may be either between the lower surface of the element isolation region EI to the bottom surface of the epitaxial layer EP or between the upper surface of the epitaxial layer EP having therein the photodiode PD or the channel region of the transistor Q1 and the lower surface of the epitaxial layer EP. In either case, the depth of the trench DT in a direction perpendicular to the main surface of the semiconductor substrate SB is greater than the depth of the trench filled with the element isolation region EI and the formation depth of the photodiode PD.

Here, a description will be made assuming that the trench DT extends from the upper surface of the epitaxial layer EP having therein the photodiode PD and the channel region of the transistor Q1 to the lower surface of the epitaxial layer EP. In short, the trench DT penetrates the element isolation region EI formed in the isolation region IR. This means that the trench DT has a width smaller than the element isolation region EI and the trench filled with the element isolation region EI.

The depth of the trench DT is equal to the thickness of the epitaxial layer EP and, for example, it is more than 5 μm and not more than 10 μm. The bottom surface of the trench DT is, in fact, presumed to reach an intermediate depth position of the semiconductor substrate SB. In the drawing, the P⁺ type semiconductor region PI extends to an intermediate depth position of the epitaxial layer EP and the bottom portion of the P⁺ type semiconductor region PI does not reach the bottom surface of the epitaxial layer EP. In other words, the bottom portion (bottom surface) of the P⁺ type semiconductor region PI is separated from the bottom surface of the epitaxial layer EP.

Such a structure is formed because the P⁺ type semiconductor region PI is formed in the upper surface of the epitaxial layer EP by ion implantation. By ion implantation, an impurity ion can be implanted into only from about 3 to 5 μm deep from the upper surface of a target substrate. As shown in FIG. 1, the isolation region IR surrounds the pixel region PER so that the epitaxial layer EP of the pixel region PER is completely separated by the trench DT from the epitaxial layer EP of the peripheral circuit region CR.

The trench DT shown in FIG. 2 has therein a DTI (deep trench isolation) structure (element isolation portion) DTI made of an insulating film IL0. The insulating film IL0 has a stacked film structure of a plurality of insulating films. A boundary between these films configuring the insulating film IL0 is however omitted from the drawing and the insulating film IL0 is shown as one film. The insulating film IL0 has a structure obtained, for example, by successively stacking, in a manufacturing step of the semiconductor device, a film having high flowability and a high covering ratio, a film having low flowability and a low covering ratio, and a film having high flowability and a high covering ratio in order of mention. These films are each made of, for example, a TEOS (tetra ethyl ortho silicate) film and the like. In short, the insulating film IL0 and the DTI structure DTI are each made of, for example, a silicon oxide film.

A portion of the insulating film IL0 covers the upper surface of the interlayer insulating film CL and the other portion of the insulating film IL0 is present in an opening portion (trench) penetrating the interlayer insulating film CL and in the trench DT penetrating the element isolation region EI and the epitaxial layer EP. The DTI structure DTI extends from the upper surface of the element isolation region EI to the bottom surface of the trench DT. This means that the bottom portion of the DTI structure DTI reaches the main surface of the semiconductor substrate SB. It is also possible to think that the DTI structure DTI extends from the upper surface of the epitaxial layer EP which is in contact with the bottom surface of the element isolation region EI to the bottom surface of the trench DT.

The insulating film IL0 has a planarized upper surface. The insulating film IL0 on the element isolation region EI and the interlayer insulating film CL configures a portion of an interlayer insulating film (contact layer). The peripheral circuit region CR has therein a plurality of contact holes penetrating the insulating film IL0 and the interlayer insulating film CL. These contact holes each reach a silicide layer (not shown) formed on the respective upper surfaces of the gate electrode GE and the source and drain regions SD. The contact holes are each filled with a plug (contact plug, coupling portion) CP mainly made of, for example, W (tungsten) and are electrically coupled to the gate electrode GE or each of the source and drain regions SC via the silicide layer.

Although not shown here, the contact holes and plugs CP are also coupled to the transfer transistor formed in the pixel region PER and each of the peripheral transistors. The plug CP is however not coupled to the photodiode PD. The upper surface of each of the plugs CP is flat at a height equal to that of the upper surface of the insulating film IL0.

The interlayer insulating film CL, the insulating film IL0, and the plug CP each have thereon a plurality of wiring layers. The number of the wiring layers can be changed as needed, but here, to facilitate understanding of the structure, a description will be made assuming that the number of the wiring layers is three. Described specifically, the interlayer insulating film CL, the insulating film IL0, and the plug CP each have thereon a first wiring layer, a second wiring layer, and a third wiring layer stacked one after another in order of mention.

The first wiring layer has a plurality of wirings M1 formed on each of the interlayer insulating film CL, the insulating film IL0, and the plug CP, an interlayer insulating film IL1 that covers the side wall and the upper portion of the wiring M1, and a plurality of vias (coupling portions) V1 that penetrate the interlayer insulating film IL1 and are coupled to the upper surface of the wirings M1. The wiring M1 is a pattern mainly made of, for example, Al (aluminum) and is coupled to the upper surface of the plug CP. This means that the wiring M1 is electrically coupled to various semiconductor elements formed in the vicinity of the upper surface of the epitaxial layer EP via the plug CP. The interlayer insulating film IL1 is made of, for example, a silicon oxide film and its upper surface is flat within the same plane as the upper surface of the via V1. The via V1 is made of, for example, a metal film composed mainly of Cu (copper) that has filled a via hole penetrating the interlayer insulating film IL1.

The second wiring layer has an interlayer insulating film IL2 formed on the first wiring layer and a plurality of wirings M2 that have filled a plurality of wiring trenches penetrating the interlayer insulating film IL2, respectively. The wiring M2 is a pattern mainly made of Cu (copper). Its upper surface is flat within the same plane as the upper surface of the interlayer insulating film IL2. The wiring M2 is electrically coupled to the wiring M1 via the via V1. The interlayer insulating film IL2 is made of, for example, a silicon oxide film.

The second wiring layer has thereon a third wiring layer via a coupling layer. The coupling layer has an interlayer insulating film ILV made of, for example, a silicon oxide film and a plurality of vias (coupling portions) V2 that penetrate the interlayer insulating film ILV and are coupled to the upper surface of the wiring M2. The third wiring layer has a wiring M3 formed on the coupling layer and an interlayer insulating film IL3 covering the side wall and the upper portion of the wiring M3. The wiring M3 is a pattern mainly made of, for example, Al (aluminum) and is coupled to the upper surface of the wiring M2 via the via V2. The interlayer insulating film IL3 is made of, for example, a silicon oxide film and it has a planarized upper surface.

In the pixel region PER, none of the wirings M1 and M2 and the vias V1 and V2 are present right above the photodiode PD. Such a structure is employed in order to prevent the wirings M1 and M2 and vias V1 and V2 made of a metal film from blocking light irradiated from above the photodiode PD through a microlens ML. The pixel region PER, however, has, at the end portion thereof, the wiring M3 so as to cover a portion right above the photodiode PD. One of the objects of forming the wiring M3 and thereby blocking a pixel PE from light is to detect a weak signal obtained at the pixel PE not exposed to light during image sensing. In a region of the pixel region PER other than the end portion, the photodiode PD does not have, right thereabove, the wiring M3.

In the pixel region PER, the third wiring layer has thereon a color filter CF and a plurality of microlenses ML. The microlenses ML are present while corresponding to the pixels, respectively. The color filter CF is a film made of a material that transmits light of a predetermined wavelength and blocks light of another wavelength. It is used for enabling each pixel PE to receive light of a desired wavelength. The pixel region PER has therein a plurality of kinds of the color filters CF. The microlens ML is made of an insulating film having a hemispherical upper surface.

At the time of image sensing, light irradiated to the image sensor passes through the microlens ML, the color filter CF, and each of the wiring layers successively and reaches the photodiode PD. Incident light is then irradiated to the PN junction of the photodiode and photoelectric conversion occurs in the photodiode PD and the epitaxial layer EP below the photodiode PD. As a result, electrons are generated and these electrons remain as a charge in the N type semiconductor region NR of the photodiode PD. Thus, the photodiode PD is a photodetector producing therein signal charges depending on the light photoelectric conversion element.

Electrons are generated by photoelectric conversion of incident light not only in the N type semiconductor region NR but also in the epitaxial layer EP below the N type semiconductor region NR. The electrons generated in the epitaxial layer EP gather in the N type semiconductor region NR where electrons are accumulated easily and they are accumulated as a charge in the N type semiconductor region NR. As the epitaxial layer EP which is a P type semiconductor layer is thicker, the quantity of electrons available by image sensing increases and the solid state image sensor thus obtained can have improved sensitivity.

The PN junction between the N type semiconductor region NR and the epitaxial layer EP also configures the photodiode PD. The heavily doped P⁺ type semiconductor region PR formed in the upper surface of the epitaxial layer EP has been described above, but the photodiode PD may be comprised of only the N type semiconductor region NR and the epitaxial layer EP without having the P⁺ type semiconductor region PR.

### <Advantage of Semiconductor Device>

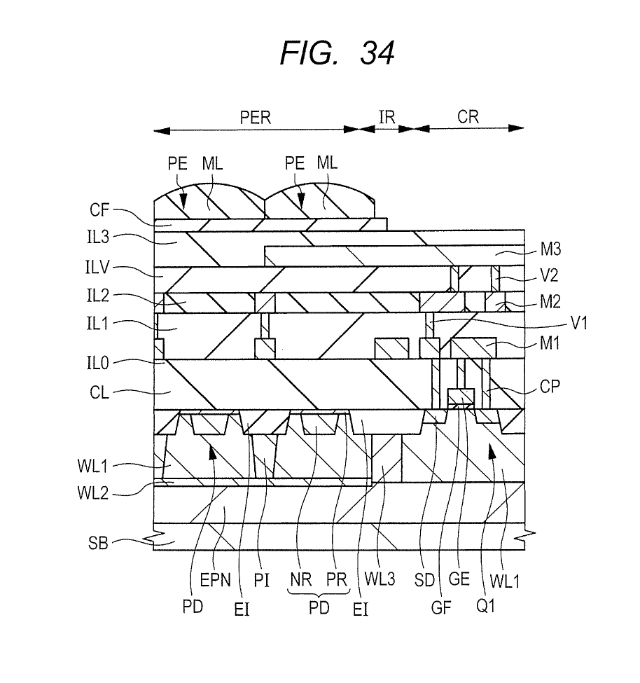

The advantage of the semiconductor device of the present embodiment will hereinafter be described referring to Comparative Example shown in FIG. 34. FIG. 34 is a cross-sectional view showing a semiconductor device of Comparative Example. FIG. 34 shows, similar to FIG. 2, an end portion of a pixel region PER, an isolation region IR, and a peripheral circuit region CR of a solid state image sensor. The solid state image sensor of the present embodiment and the solid state image sensor of Comparative Example are each an element for receiving near infrared light and thereby carrying out image sensing.

The solid state image sensor of Comparative Example has an N type semiconductor substrate SB and an N type epitaxial layer EPN formed thereon. The epitaxial layer EPN in the pixel region PER and the peripheral circuit region CR have, in the upper surface thereof, a P type well (semiconductor region) WL1 extending from the upper surface of the epitaxial layer EPN to an intermediate depth portion of the epitaxial layer EPN. The structure of the element isolation region EI, the photodiode PD, and the transistor Q1 in the pixel region PER and the peripheral circuit region CR is similar to that of the present embodiment. The structure on the epitaxial layer EPN is similar to that of the present embodiment except that the epitaxial layer EPN has no insulating film IL0 (refer to FIG. 2) thereon.

The well WL1 in the pixel region PER has, at the bottom portion thereof, a P⁺ type well WL2 having a P type impurity concentration higher than that of the well WL1. In the isolation region IR, the element isolation region EI has, below the bottom surface thereof, an N type well WL3 extending from the upper surface of the epitaxial layer EPN to an intermediate depth portion of the epitaxial layer EPN. The well WL3 is formed so as to isolate the well WL1 of the pixel region PER from the well WL1 of the peripheral circuit region CR. Described specifically, since electrons are accumulated easily in the well WL3, it prevents electrons generated in the well WL1 in the peripheral circuit region CR from passing through the well WL3, moving to the pixel region PER, and thereby preventing a pixel PE from detecting an incorrect signal.

The well WL3 has therefore a depth equal to that of the well WL1. The formation depth of the well WL1 is, for example, from 3 to 5 μm from the upper surface of the epitaxial layer EPN. This value, from 3 to 5 μm, is a limit value that enables formation of the P type well WL1 by ion implantation using an impurity ion implantation apparatus. It is difficult to form a well deeper than the above-described one because it may cause many defects in the epitaxial layer EPN.

In an image sensor that receives near infrared light having a long wavelength, with an increase in the formation depth of the P type semiconductor region, that is, the well WL1, the quantity of electrons available by image sensing increases and the resulting solid state image sensor can have improved sensitivity. Even when electrons are generated in the N type epitaxial layer EPN and the semiconductor substrate SB below the wells WL1 and WL2, these electrons stay in the epitaxial layer EPN and the semiconductor substrate SB where charges are easily accumulated so that these electrons cannot be detected by the photodiode PD.

In Comparative Example, since the formation depth of the P type wells WL1 and WL2 is limited, it is difficult to provide an image sensor having improved sensitivity by enlarging a region where photoelectric conversion is performed. In particular, near infrared light has a wavelength longer than that of visible light so that the image sensor cannot have improved sensitivity when the depth of the P type semiconductor region where photoelectric conversion can be carried out, in other words, the depth of the well WL1 is small.

The present inventors investigated formation of an image sensor by using a semiconductor substrate available by forming a P type epitaxial layer on a P type semiconductor substrate. In forming this image sensor, the thickness of the epitaxial layer was made greater than 5 μm in order to enlarge a region where charges were generated. As a result, the sensitivity of a near infrared light was made twice as much as that of Comparative Example. The present inventors however found the following problems.

There occur two problems. First one is that formation of a P type epitaxial layer on a P type semiconductor substrate leads to an increase in dark current. Second one is that an image obtained by image sensing has unevenness because noise or dark current occurs frequently in pixels in the vicinity of a peripheral circuit region. These problems occur because the semiconductor substrate and the epitaxial layer coupled to each other have the same conductivity type so that electrons travel easily inside the semiconductor substrate and the epitaxial layer.

For example, a dark current or noise is caused by transfer of electrons generated in the semiconductor substrate transfer to the epitaxial layer in the pixel region or transfer of electrons in the epitaxial layer in the peripheral circuit region to the epitaxial layer in the pixel region. The noise occurs due to transfer of electrons from the peripheral circuit to the pixel region. Even if the N type well WL3 shown in FIG. 34 is formed, however, transfer of electrons between the peripheral circuit region and the pixel region cannot be prevented. The reason is that even if the well WL3 is formed in the upper surface of the epitaxial layer having a depth greater than 5 μm by ion implantation, the well WL3 does not reach the bottom portion of the epitaxial layer due to a limitation in the formation depth of the well WL3. Electrons generated in the peripheral circuit region move in the epitaxial layer or semiconductor substrate below the well WL3 and are detected by a pixel.

In addition, even when a DTI structure extending from the upper surface of the epitaxial layer to the upper surface of the semiconductor substrate is formed in the isolation region between the pixel region and the peripheral circuit region, such transfer of electrons cannot be prevented, because electrons generated in the peripheral circuit region travel in the P type semiconductor substrate below the DTI structure and then move to the epitaxial layer in the pixel region. Thus, it is difficult to prevent generation of a dark current and the like in a solid state image sensor having, as a substrate, a P type semiconductor substrate and a P type epitaxial layer, though the image sensor can have improved sensitivity.

The present inventors have therefore found that both improvement in sensitivity and prevention of a dark current and noise can be satisfied by forming a P type epitaxial layer on an N⁻ type semiconductor substrate and forming a DTI structure penetrating the epitaxial layer. As shown in FIG. 2, in the present embodiment, the N⁻ type semiconductor substrate SB has thereon the P type epitaxial layer EP and the isolation region IR has therein the DTI structure DTI penetrating the epitaxial layer EP.

Compared with Comparative Example in which the P type well WL1 (refer to FIG. 34) is formed by ion implantation, a photoelectric conversion region (depth) can be widened by forming the P type epitaxial layer EP with a thickness of 5 μm or greater. The solid state image sensor thus obtained can therefore have improved sensitivity. Since near infrared light has a wavelength longer than that of visible light, providing a photoelectric conversion region greater in a light irradiation direction is effective from the standpoint of sensitivity improvement.

At this time, even if electrons are generated in the N⁻ type semiconductor substrate SB or electrons generated in the epitaxial layer EP move in the semiconductor substrate SB, these electrons can be prevented from traveling in the epitaxial layer to become a dark current. The electrons in the semiconductor substrate SB do not easily transfer to the P type epitaxial layer EP because the semiconductor substrate SB has an N conductivity type and the electrons in the semiconductor substrate SB are major carriers. This makes it possible to prevent electrons generated right below the photodiode PD from transferring to a pixel PE other than the pixel PE having therein the photodiode PD and electrons in the epitaxial layer EP in the peripheral circuit region CR can be prevented from transferring to the pixel PE via the semiconductor substrate SB. As a result, occurrence of a dark current and noise in the pixel region PER can be prevented.

In addition, the isolation region IR has therein the DTI structure DTI extending from the upper surface of the epitaxial layer EP to the upper surface of the semiconductor substrate SB so that electrons in the epitaxial layer EP in the peripheral circuit region CR can be prevented from transferring to the pixel region PER. In other words, the DTI structure DTI isolates between the respective epitaxial layers EP in the peripheral circuit region CR and in the pixel region PER so that direct transfer of electrons between these epitaxial layers EP can be prevented. In addition, since the bottom portion of the DTI structure DTI is in contact with the upper surface of the N⁻ type semiconductor substrate SB, electrons in the epitaxial layer EP in the peripheral circuit region CR can be prevented from transferring to the pixel region PER via the semiconductor substrate SB. As a result, generation of a dark current and noise in the pixel region PER can be prevented.

The semiconductor device of the present embodiment can therefore have improved performance because the solid state image sensor can have improved sensitivity and be prevented from causing a dark current and noise.

Transfer of electrons between the peripheral circuit region CR and the pixel region PER cannot be prevented even when the N type well WL3 or P type well is formed by ion implantation as in Comparative Example without forming the DTI structure in the isolation region IR of the solid state image sensor having the N⁻ type semiconductor substrate SB and the P type epitaxial layer EP. This is because these wells cannot extend deeply to the bottom portion of the epitaxial layer EP when formed by ion implantation.

### <Method of Manufacturing Semiconductor Device>

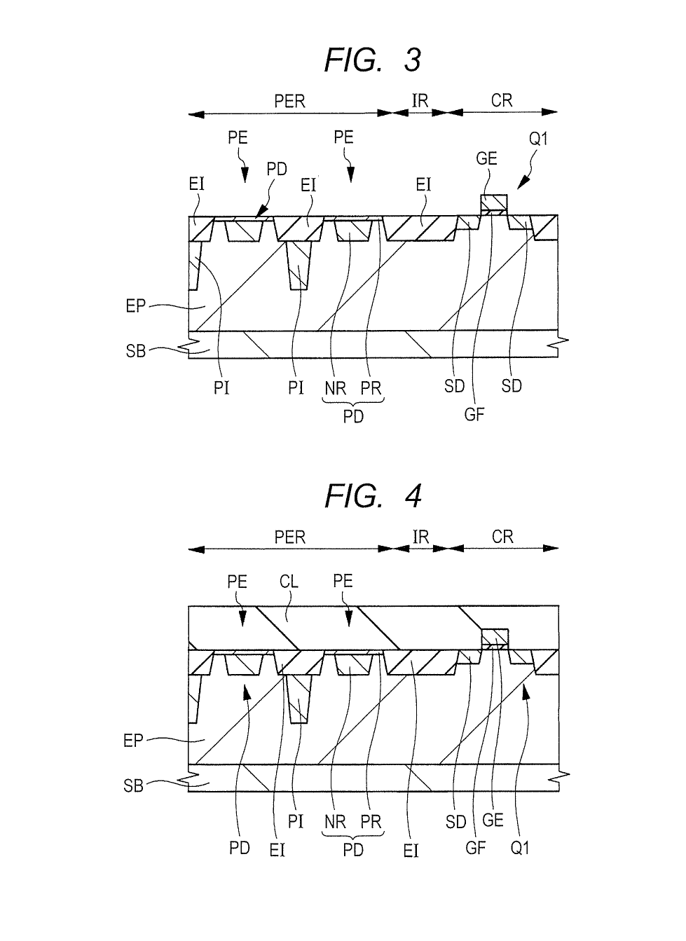

A method of manufacturing the semiconductor device of the present embodiment will hereinafter be described referring to FIGS. 3 to 9. FIGS. 3 to 9 are cross-sectional views describing manufacturing steps of the semiconductor device of the present embodiment and they are views of a position corresponding to that of FIG. 2. This means that in each of FIGS. 3 to 9, a pixel region PER, an isolation region IR, and a peripheral circuit region CR are shown in order of mention from the left side. The pixel region PER is surrounded by the peripheral circuit region CR as shown in FIG. 1 and the pixel region PER and the peripheral circuit region CR have therebetween the isolation region IR.

In the manufacturing steps of the semiconductor device, first, as shown in FIG. 3, an N⁻ type semiconductor substrate SB made of, for example, single crystal silicon (Si) is provided. Then, a P type epitaxial layer EP is formed on the upper surface of the semiconductor substrate SB by epitaxial growth. The epitaxial layer EP has a thickness more than 5 μm and not more than 10 μm. In the step of forming the epitaxial layer EP, an epitaxial growth layer is formed while adding B (boron) onto the semiconductor substrate SB. The epitaxial layer EP thus formed therefore becomes a relatively lightly-doped P type semiconductor layer.

Next, a plurality of trenches is formed in the main surface of the epitaxial layer EP and an element isolation region EI is formed in each of these trenches. By this, an active region, which is a region in which the upper surface of the semiconductor substrate SB is exposed from the element isolation region EI is defined (partitioned). The element isolation region EI can be formed, for example, by STI or LOCOS. The element isolation region EI here is formed by STI. The element isolation region EI is made of a silicon oxide film formed in the trench, for example, CVD (chemical vapor deposition). In the isolation region IR, the element isolation region EI is formed so as to surround the pixel region PER in plan view. By defining the active region, a plurality of pixels PE arranged in matrix form is formed in the pixel region PER.

Next, impurity implantation for isolating two adjacent pixels PE from each other, that is, pixel-pixel isolation implantation is performed. A P⁺ type semiconductor region PI is formed in the upper surface of the semiconductor substrate by implanting, by ion implantation or the like, a P type impurity (for example, B (boron)) into the upper surface of the epitaxial layer EP right below the element isolation region EI between the two adjacent pixels PE. Since the epitaxial layer EP is thick, the bottom portion of the P⁺ type semiconductor region PI does not reach the main surface of the semiconductor substrate SB.

By the pixel-pixel isolation implantation, a potential barrier against electrons is formed between pixels PE to be formed later. This makes it possible to prevent diffusion of electrons between the pixels PE adjacent to each other and thereby provide an image sensor having improved sensitivity characteristics.

Next, a gate electrode GE is formed on the epitaxial layer EP via a gate insulating film GF. Here, after formation of a silicon oxide film on the epitaxial layer EP, for example, by the oxidation method, a polysilicon film is formed on the silicon oxide film, for example, by CVD. Then, the polysilicon film and the silicon oxide film are processed using photolithography and etching to form a gate electrode GE made of the polysilicon film and a gate insulating film made of the silicon oxide film. In this step, in a region where the pixel region PER is not shown, also a gate insulating film and a gate electrode configuring a transfer transistor or a peripheral transistor are famed.

Next, a photodiode PD including the N type semiconductor region NR and the P⁺ type semiconductor region PR is formed in the upper surface of the epitaxial layer EP in the pixel region PER. Described specifically, an N type semiconductor region NR is formed in a portion of the active region where a light receiving portion is to be formed by implanting an N type impurity (for example, arsenic (As) or P (phosphorus)) into the main surface of the semiconductor substrate SB of the pixel region PER, for example, by ion implantation. In addition, by implanting a P type impurity (for example, B (boron)) into the main surface of the semiconductor substrate SB of the pixel region PER, for example, by ion implantation, a P⁺ type semiconductor region PR is formed in a portion of the active region where the light receiving portion is to be formed. The formation depth of the N type semiconductor region NR is shallower than that of the P⁺ type semiconductor region PI.

Here, implantation by the ion implantation is performed with a photoresist film (not shown) and a gate electrode of the transfer transistor as a mask (implantation preventing mask).

Next, source and drain regions SD, which are N type impurity regions, are formed by implanting, for example, by ion implantation, an N type impurity (for example, arsenic (As) or P (phosphorus)) into a portion of the active region having no photodiode PD therein. By this step, a floating diffusion region (floating diffusion capacitance portion) configuring a drain region of the transfer transistor is formed. An N channel type transistor Q1 having the source and drain regions SD and the gate electrode GE are thus formed in the peripheral circuit region CR. In a portion of the pixel region PER not shown in the drawing, a transfer transistor having the floating diffusion region as a drain region and the N type semiconductor region NR as a source region is formed. In each of the pixels PE in the pixel region PER, an amplifier transistor, a reset transistor, and a selection transistor having source and drain regions and a gate electrode are formed as a peripheral transistor.

Although not shown in the drawing, a silicide layer is formed on the respective upper surfaces of the source and drain regions SD and the gate electrode GE by performing a known salicide process after formation of an insulating film that covers the pixel region PER and the isolation region IR and exposes the transistor Q1 of the peripheral circuit region CR. The silicide layer (not shown) is made of, for example, NiSi (nickel silicon) or CoSi (cobalt silicon).

The silicide layer can be formed by foiling the insulating film (not shown), forming a metal film mainly composed of Ni (nickel) or Co (cobalt) by sputtering so as to cover, with this metal film, the insulating film and the upper portion of and the transistor Q1, and then heat treating to react the metal film with the respective upper surfaces of the source and drain regions SD and the gate electrode GE. After that, an unreacted extra portion of the metal film is removed. Thus, the structure shown in FIG. 3 can be obtained.

Next, as shown in FIG. 4, an interlayer insulating film CL is formed on the epitaxial layer EP. The interlayer insulating film CL is formed, for example, by stacking a silicon nitride film and a silicon oxide film on the epitaxial layer EP by CVD or the like. This means that the interlayer insulating film CL is a film stack containing a liner film made of the silicon nitride film and a thick silicon oxide film thereon. The liner film functions as an etching stopper film when a contact hole is formed later. Here, the liner film and the silicon oxide film are shown as one film. Then, the upper surface of the interlayer insulating film CL is polished and thereby planarized, for example, by CMP (chemical mechanical polishing).

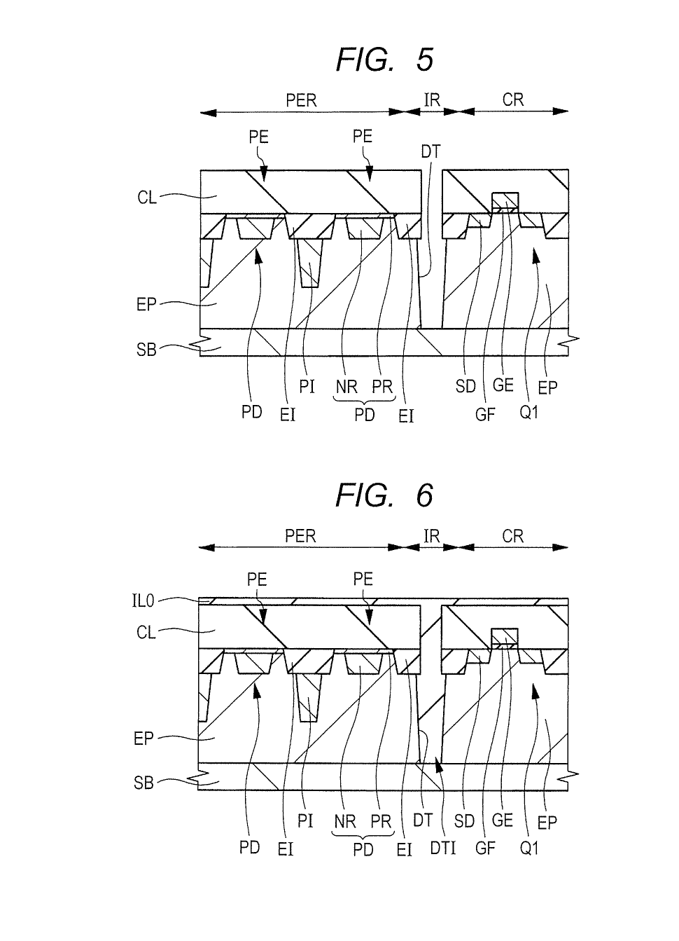

Next, as shown in FIG. 5, after formation of a photoresist pattern on the interlayer insulating film CL by photolithography, etching is performed with the photoresist pattern as a mask to remove the interlayer insulating film CL and the element isolation region EI from the isolation region IR. The upper surface of the epitaxial layer EP covered with the element isolation region EI is thereby exposed.

After removal of the photoresist pattern, dry etching is performed with the interlayer insulating film CL as a mask to make an opening in the epitaxial layer EP in the isolation region IR. In other words, a trench DT penetrating the epitaxial layer EP is formed in the isolation region IR. In this dry etching step, etching is performed with etching selectivity relative to the silicon oxide film and silicon nitride film and a high etching rate relative to these silicon films. The trench DT and the opening portion thereabove surround the pixel region PER in plan view. The main surface of the semiconductor substrate SB is exposed from the bottom surface of the trench DT.

Next, as shown in FIG. 6, the trench DT is completely filled with an insulating film IL0 by forming (depositing) the insulating film IL0 on the epitaxial layer EP and in the trench DT, for example, by CVD. A DTI structure DTI comprised of the insulating film IL0 is thereby formed in the trench DT. The insulating film IL0 comprised of a plurality of insulating films is formed by stacking the plurality of insulating films. Alternatively, the insulating film IL0 may be made of a single film. In the present embodiment, the trench DT is filled completely with the insulating film IL0 without having a space in the trench DT.

In the step of forming the insulating film IL0, a film or films configuring the insulating film IL0 are formed and then the film(s) having flowability are heated in order to cure them. This heating means RTA (rapid thermal annealing) and heating is performed at a temperature of 700° C. or less. In the manufacturing steps of the present embodiment, all the steps after formation of the trench DT are performed at 700° C. or less.

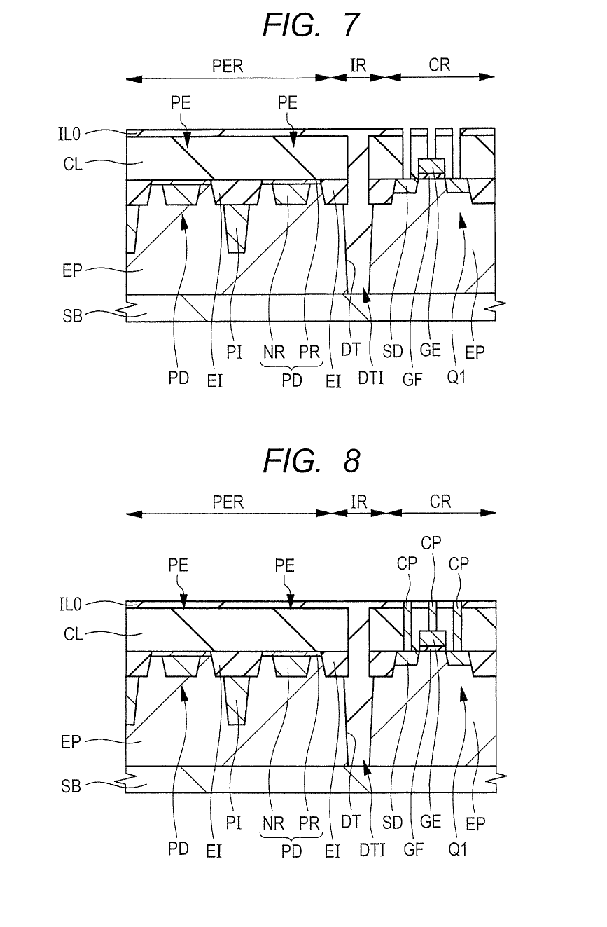

Next, as shown in FIG. 7, a photoresist pattern (not shown) is formed on the interlayer insulating film CL and, by dry etching with the photoresist pattern as a mask, the insulating film IL0 and the interlayer insulating film CL are processed to form a plurality of contact holes. At the bottom portion of the contact holes, the gate electrode GE and the source and drain regions SD are each exposed from the insulating film IL0 and the interlayer insulating film CL. This means that the contact holes penetrate the insulating film IL0 and the interlayer insulating film CL. From the bottom portion of the contact holes, the silicide layer (not shown) that has covered the respective upper surfaces of the gate electrode GE and the source-drain regions SD is exposed. In this step, contact holes that expose the respective electrodes of the transfer transistor and the peripheral transistor which are not shown in this drawing are also formed.

Next, as shown in FIG. 8, after formation of a metal film on the insulating film IL0 and in a plurality of contact holes, the metal film on the insulating film IL0 is polished and removed, for example, by CMP. By exposing the upper surface of the insulating film IL0, plugs (contact plugs) CP comprised of the metal film that has filled the contact holes are formed, respectively. The plug CP is comprised of a film stack having a titanium nitride film that has covered the side wall and the bottom surface in the contact holes and a tungsten film formed on the bottom surface to fill the contact holes via the titanium nitride film. The titanium nitride film is a barrier metal film and is formed by CVD or sputtering. The tungsten film is a main conductor film and is formed, for example, by CVD.

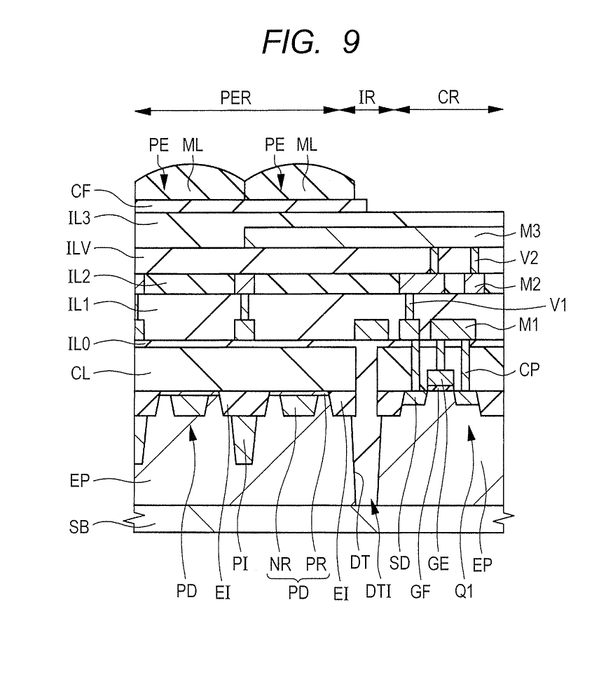

Next, as shown in FIG. 9, a first wiring layer, a second wiring layer, a coupling layer, a third wiring layer, a color filter CF, and a microlens ML are formed in order of mention on each of the insulating film IL0 and the plug CP. The semiconductor substrate SB can be cut into individual pieces by dicing to obtain a plurality of semiconductor chips, that is, a plurality of solid state image sensors. The dicing step is performed along a scribe line (not shown) surrounding the peripheral circuit region CR in plan view. As a result, the semiconductor device of the present embodiment is completed.

More specifically, after the structure shown in FIG. 8 is obtained, an aluminum film is formed, for example, by sputtering on each of the insulating film IL0 and the plug CP as shown in FIG. 9. Then, the aluminum film is processed using photolithography and etching to form a wiring M1 comprised of the aluminum film and electrically coupled to the plug CP. In each pixel PE, the aluminum film is not left right above the photodiode PD.

Next, an interlayer insulating film IL1 made of a silicon oxide film is formed using, for example, CVD on the insulating film IL0 and the wiring M1. The upper surface of the interlayer insulating film IL1 is then polished, for example, by CMP, followed by formation of a plurality of via holes that penetrates the interlayer insulating film IL1 and exposes the upper surface of the wiring M1 by photolithography and etching. After formation of a copper film on the interlayer insulating film IL1 by sputtering so as to fill each of the via holes, the copper film on the interlayer insulating film IL1 is removed by CMP or the like to form a via V1 comprised of the copper film in each of the via holes. Thus, a first wiring layer having the wiring M1, the interlayer insulating film IL1, and the via V1 is formed.

Then, an interlayer insulating film IL2 made of a silicon oxide film is formed on the first wiring layer, for example, by CVD. Then, a plurality of wiring trenches that penetrate the interlayer insulating film IL2 and expose the upper surface of the via V1 is formed using photolithography and etching. A step similar to the step of forming the via V1 is then performed to form a wiring M2 made of a copper film that fills each of the wiring trenches. Thus, the wiring M2 is formed by a so-called single damascene process. The interlayer insulating film IL2 and the wiring M2 configure a second wiring layer.

Next, a step similar to the step of forming the second wiring layer is performed to form a coupling layer. Described specifically, after formation of an interlayer insulating film ILV on the second wiring layer, a plurality of via holes that penetrate the interlayer insulating film ILV and expose the upper surface of the wiring M2 is formed. Then, a via V2 made of a copper film that fills each of the via holes is formed. The interlayer insulating film ILV and the via V2 configure the coupling layer.

Next, a step similar to the step of forming the wiring M1 and the interlayer insulating film IL1 is performed to form a wiring M3 and an interlayer insulating film IL3 on the coupling layer. Described specifically, a plurality of patterns of the wiring M3 made of an aluminum film and coupled to the via V2 is formed and then an interlayer insulating film IL3 that covers the plurality of wirings M3 is formed on the interlayer insulating film ILV. A third wiring layer comprised of the wiring M3 and the interlayer insulating film IL3 is thereby formed.

A color filter CF is formed, for example, by forming a film made of a material that transmits light of a predetermined wavelength and blocks light of the other wavelength on the interlayer insulating film IL3. A microlens ML on the color filter CF is formed by processing a film formed on the color filter CF into a circular pattern in plan view, heating the film to round the surface portion of the film including the upper surface and the side wall thereof, and thereby processing it to have a lens shape.

### <Advantage of Method of Manufacturing Semiconductor Device>

The advantage of the method of manufacturing a semiconductor device according to the present embodiment will hereinafter be described.

As described referring to Comparative Example shown in FIG. 34, it is difficult to improve the sensitivity to near infrared light when a P type well WL1 is formed on the upper surface of the substrate including the N type semiconductor substrate SB and the N type epitaxial layer EPN. When an image sensor is formed using a substrate including a P type semiconductor substrate and a P type epitaxial layer, on the other hand, improved sensitivity can be achieved, but problems, that is, dark current and noise occur.

In the method of manufacturing a semiconductor device according to the present embodiment, as described referring to FIGS. 3 to 9, improvement in sensitivity of an image sensor and prevention of dark current and noise are achieved by forming a P type epitaxial layer EP on the N⁻ type semiconductor substrate SB and then forming a DTI structure DTI penetrating the epitaxial layer EP in the isolation region IR. This means that an advantage similar to that described for the semiconductor device of the present embodiment can be attained.

In addition, the place where the DTI structure DTI is formed is limited to a region where the element isolation region EI has been formed. This means that the trench DT is not formed in the active region. In other words, each of the entirety of the DTI structure DTI and the trench DT is formed within the element isolation region EI formed in the isolation region IR in plan view. This makes it possible to prevent damage, during etching for forming the trench DT and the opening portion of the interlayer insulating film CL on the trench DT, to the upper surface of the epitaxial layer EP in the active region from affecting a semiconductor element formed in the active region in the pixel region PER or active region in the peripheral circuit region CR.

Here, the trench DT and the DTI structure DTI are formed after formation of semiconductor elements such as transistor Q1, transfer transistor, peripheral transistor, and photodiode PD and the maximum temperature during forming the insulating film IL0 configuring the DTI structure DTI is set at 700° C. This makes it possible to prevent the temperature in the step of forming the DTI structure DTI from varying the characteristics of semiconductor elements such as transistors.

In the present embodiment, since etching damage at the time of forming the trench DT can be prevented from affecting elements and at the same time, variations in the characteristics of semiconductor elements depending on the temperature in the manufacturing steps can be prevented, it is not necessary to re-adjust element formation conditions which will otherwise be required when steps of forming the trench DT and the DTI structure DTI are added. The development term of the semiconductor device can therefore be shortened and a manufacturing cost can be reduced.

### Modification Example

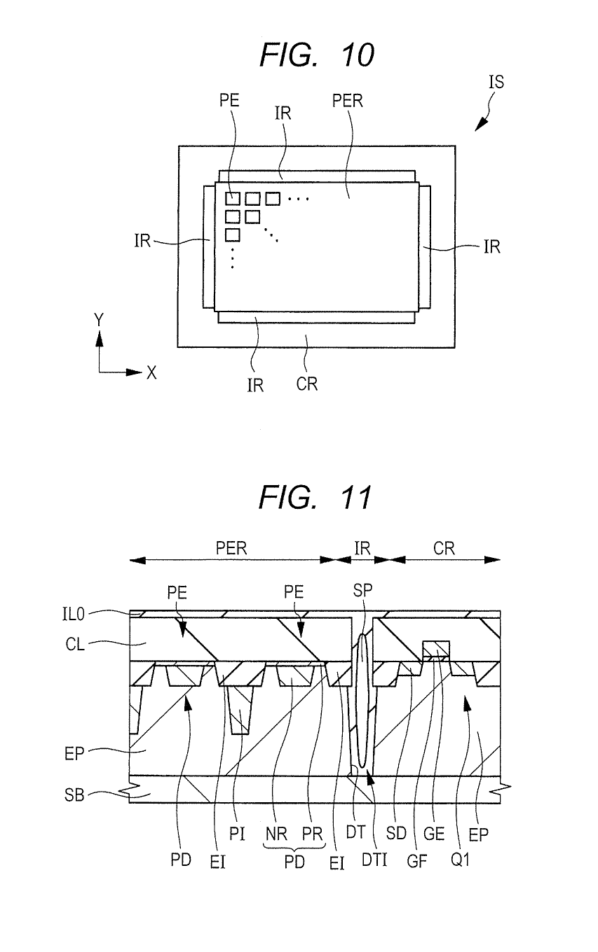

A modification example of the semiconductor device and the method of manufacturing same according to the present embodiment will hereinafter be described referring to FIG. 10. FIG. 10 is a plan view showing a semiconductor device of a modification example of the present embodiment and it corresponds to FIG. 1.

In FIG. 1, the isolation region IR is formed as a region having a rectangular closed structure in plan view. Alternatively, it is possible to employ such a layout that an isolation region IR is not formed at the corner portion of the rectangular region and the corner portion of the rectangular pixel region PER comes into contact with the peripheral circuit region CR. This means that, as shown in FIG. 10, the isolation region is not formed as a closed region but four isolation regions IR may be placed along the four sides of the pixel region PER having a rectangular shape in plan view.

In this case, similar to the isolation regions IR shown in FIG. 10, four DTI structures, each as shown in FIG. 3, are formed along the four sides of the pixel region PER. The end portions of these four DTI structures DTI in their extending directions are separated from each other without being coupled. Between the corner portion of the pixel region PER and the peripheral circuit region CR, no trench DT (refer to FIG. 3) penetrating the epitaxial layer EP is formed.

In plan view, the width of the trench DT along the four side of the pixel region PER and in a direction along which the four sides orthogonally intersect with each other is fixed. When the DTI structure DTI in the isolation region IR has a layout having a rectangular closed structure in plan view, a length of the diagonal line between the corner portion of the pixel region PER and the outer corner portion of the isolation region IR is greater than the above-described width of the trench DT. This means that the trench DT having a rectangular closed structure has, at the corner portion in plan view, a portion having a width greater than that of another region. When a DTI structure DTI is formed by filling a large-width trench DT with it, the DTI structure DTI cannot be formed with a stable shape and as a result, the semiconductor device thus obtained may have deteriorated reliability.

In the present modification example, no DTI structure DTI is formed in the vicinity of the corner portion of the pixel region PER. This means that the DTI structure does not have a folded layout so that the trench DT can be filled stably with it.

### Second Embodiment

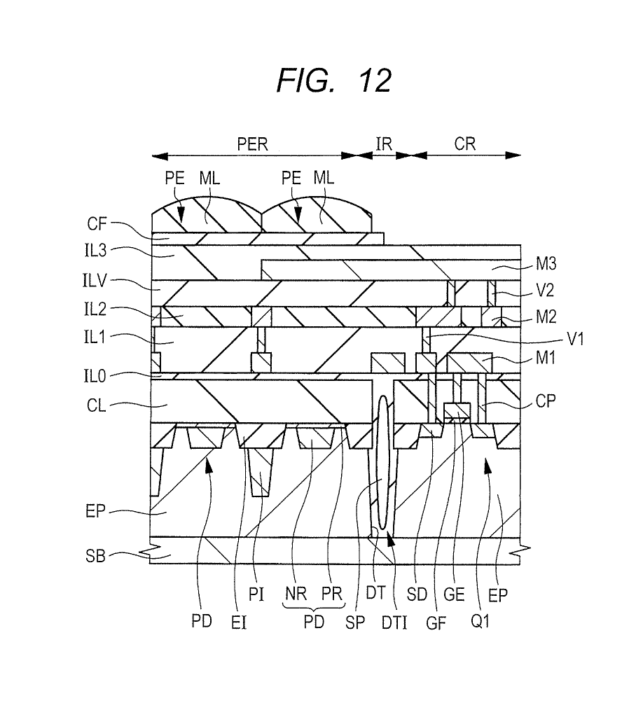

The structure of a semiconductor device according to Second Embodiment and a manufacturing method of it will hereinafter be described referring to FIGS. 11 and 12. Here, a description will be made on the formation of a space inside the DTI structure. FIGS. 11 and 12 are cross-sectional views describing manufacturing steps of the semiconductor device of the present embodiment.

Here, steps similar to those described referring to FIGS. 3 to 5 are performed to form elements such as photodiode PD and transistor Q1 in the vicinity of the upper surface of the substrate and then, an interlayer insulating film CL and a trench DT are formed.

Next, as shown in FIG. 11, by forming an insulating film IL0 on the epitaxial layer EP and in the trench DT, for example, by CVD, the upper surface of the interlayer insulating film CL is covered with the insulating film IL0 and the trench DT is filled with the insulating film IL0. The trench DT is however not completely filled with the insulating film IL0 and a space SP surrounded by the insulating film IL0 is formed at the center portion in the trench DT. Thus, a DTI structure DTI having the insulating film IL0 and the space SP in the trench DT is formed.

The insulating film IL0 is made of a single-layer or a multi-layer film. It has at least a film having low flowability and low film forming property during a film formation step.

When the insulating film IL0 is made of a multi-layer film, a first insulating film having high flowability and high film formation property is formed by CVD after obtaining the structure shown in FIG. 5. At this time, the trench DT is not completely filled.

Then, a second insulating film having low flowability and low film forming property is formed by CVD. The second insulating film has a greater thickness at the upper portion of the trench DT than at the lower portion of the trench DT. At the upper portion of the trench DT, portions of the second insulating film that cover the respective side walls of the trench DT opposite to each other have a greater thickness so that they become close to each other. The portions of the second insulating film that cover the respective side walls of the trench DT opposite to each other may come into contact with each other or not. In other words, at the time of completion of the formation of the second insulating film, the trench DT may have therein a closed space SP or alternatively, it may not yet have therein a space SP because the portions of the second insulating film are not closed with each other.

Then, a third insulating film having high flowability and high film forming property is formed by CVD. As a result, formation of an insulating film IL0 comprised of the first insulating film, the second insulating film, and the third insulating film is completed. When the portions of the second insulating film are closed with each other in the trench DT and form a closed space SP, the third insulating film is deposited over the space SP. When the portions of the second insulating film are not closed with each other in the trench DT, the third insulating film covers the surface in the trench DT and at the same time, portions of the third insulating film on the respective side walls of the trench DT opposite to each other come into contact with each other at the upper portion of the trench DT. In short, portions of the insulating film IL0 are closed with each other at the upper portion of the trench DT and a space SP is thereby formed.

The first insulating film and the third insulating film are each made of an O₃TEOS film. For example, the first insulating film and the third insulating film made of an O₃TEOS film have good step coverage and have good flowability. Even when the trench DT has, on the side surface thereof, irregularities called “scallop”, by forming a first insulating film made of an O₃TEOS film on the side surface of the trench DT, the first insulating film formed on the side surface of the trench DT can have a flat surface. In other words, formation of the first insulating film having good flowability is required to cover such irregularities and planarize the surface in the trench DT.

The second insulating film can be formed, for example, By PECVD using a gas containing a tetraethoxysilane (TEOS) gas. A silicon oxide film formed by plasma-enhanced chemical vapor deposition (PECVD) using this gas containing a TEOS gas is called “PTEOS film”.

The second insulating film made of a silicon oxide film may be formed by PECVD using a gas containing a silane (SiH₄) gas instead of a TEOS gas. The silicon oxide film formed by PECVD using this gas containing SiH₄ gas is called “P—SiO film”. A film made of PTEOS or P—SiO may hereinafter be called “PTEOS film or the like”.

The step coverage of the PTEOS film or the like is lower than the step coverage of each of the first insulating film and the third insulating film made of an O₃TEOS film. The flowability of the PTEOS film or the like is lower than that of the O₃TEOS film. This means that the second insulating film has characteristics inferior in film forming performance and coverage to the first insulating film and the third insulating film. When a layer having the side wall and the upper surface is covered with the second insulating film, the thickness of the second insulating film formed on the side wall is smaller than that of the second insulating film formed on the upper surface. In particular, the thickness of the second insulating film extending along the side wall is smaller at the lower portion of the second insulating film than at the upper portion of the second insulating film.

Although the first insulating film, the second insulating film, and the third insulating film differ in flowability at the time of formation of the respective films, any of them has flowability at the time of film formation. The first insulating film, the second insulating film, and the third insulating film should be subjected to heat treatment (RTA) and thereby solidified whenever they are formed. The temperature at the heat treatment performed three times in total for the first insulating film, the second insulating film, and the third insulating film, respectively, is 700° C. or less.

After formation of the insulating film IL0, the upper surface of the insulating film IL0 is polished and planarized, for example, by CMP. The upper surface of the interlayer insulating film CL is however not exposed from the insulating film IL0. Steps subsequent thereto are performed similarly to the steps described referring to FIGS. 7 to 9 to obtain an image sensor shown in FIG. 12. As a result, the semiconductor device of the present embodiment is completed.

The image sensor of the present embodiment is different from that of First Embodiment in that it has the space SP in the DTI structure DTI. The space SP extends from the vicinity of the bottom portion to the upper portion of the trench DT and has a vertically long shape. The DTI structure DTI for electrically isolating between elements has a high insulation property when it has the space SP. The present embodiment can produce an advantage similar to that of First Embodiment and in addition, can enhance the insulation property between the pixel region PER and the peripheral circuit region CR. This means that since the possibility of electrons moving between the pixel region PER and the peripheral circuit region CR can be reduced, occurrence of dark current and noise can be prevented effectively.

When a peripheral circuit including the transistor Q1 is driven, a trace amount of light is emitted from an element such as transistor Q1. Light emitted from the transistor Q1 and entering the pixel region PER may be a cause of dark current and noise. In the present embodiment, on the other hand, the space SP present in the trench DT can reflect the light to the side of the peripheral circuit region CR and prevent the light from entering a photoelectric conversion region of the pixel region PER.

When light generated at the peripheral circuit region CR reaches the side wall of the space SP, for example, via the epitaxial layer EP and the insulating film IL0, reflection occurs due to a difference in refractive index between the insulating film IL0 and the space SP and the light returns to the side of the peripheral circuit region CR. This makes it possible to prevent generation of dark current and the like.

### Modification Example 1

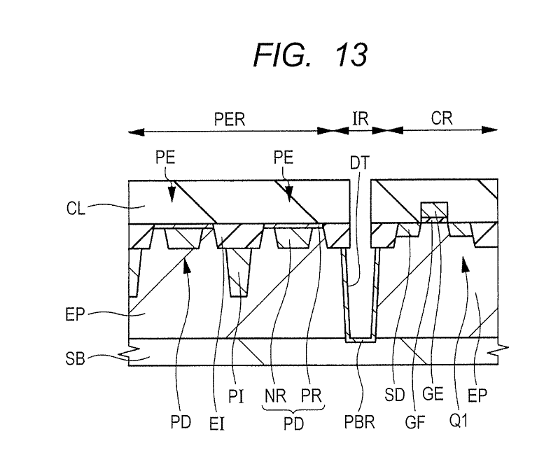

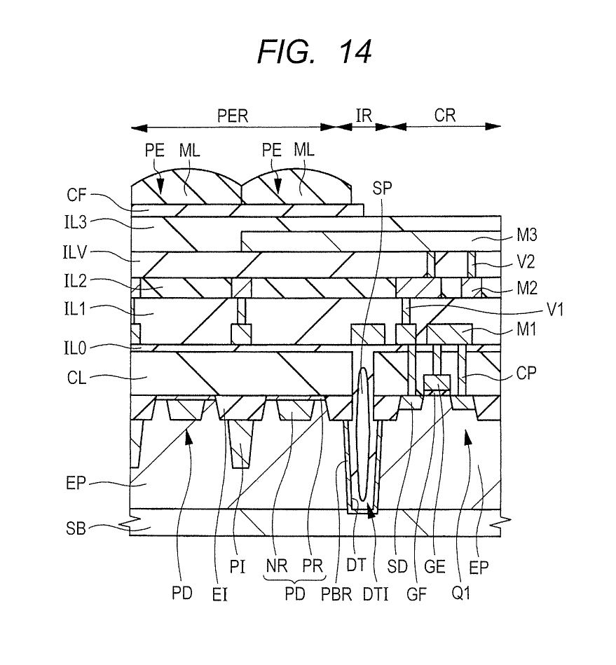

The structure and manufacturing method of a semiconductor device of Modification Example 1 of Second Embodiment will next be described referring to FIGS. 13 and 14. Here, a description will be made on the formation of a P type semiconductor region in the surface of the semiconductor substrate and epitaxial layer in the vicinity of a trench filled with a DTI structure. FIGS. 13 and 14 are cross-sectional views describing manufacturing steps of the semiconductor device of Modification Example 1 of the present embodiment.

First, steps similar to those described referring to FIGS. 3 to 5 are performed to form elements such as photodiode PD and transistor Q1 in the vicinity of the upper surface of the substrate and also an interlayer insulating film CL and a trench DT.

Next, as shown in FIG. 11, an insulating film IL0 is formed on the epitaxial layer EP and also in the trench DT, for example, by CVD to cover the upper surface of the interlayer insulating film CL with the insulating film IL0 and fill the trench DT with the insulating film IL0. The trench DT is however not completely filled with the insulating film IL0 and a space SP surrounded with the insulating film IL0 is formed at the center portion in the trench DT. By this step, a DTI structure DTI having the insulating film IL0 and the space SP therein is formed in the trench DT.

Next, as shown in FIG. 13, by carrying out an ion implantation step with the interlayer insulating film CL as a mask (ion implantation preventing mask), a P type impurity (for example, B (boron) or BF₂ (boron difluoride)) is implanted into the respective surfaces of the semiconductor substrate SB and the epitaxial layer EP, which are surfaces of the trench DT. The trench DT therefore has, on the surface thereof, a P type semiconductor region PBR. In the ion implantation step, ion implantation may be performed in an oblique direction relative to the main surface of the semiconductor substrate SB. The peak concentration of the P type impurity in the P type semiconductor region PBR is, for example, 1×10¹⁷ atm/cm³.

The P type semiconductor region PBR is foiled by ion implantation as described above, but the P type semiconductor region PBR may be formed by plasma doping. Described specifically, the P type semiconductor region PBR can be formed by a method of forming a trench DT to obtain the structure shown in FIG. 5, applying a bias voltage to the semiconductor substrate SB in a plasmanized boron ion atmosphere, and thereby introducing boron into the surface of the trench DT.

Alternatively, the P type semiconductor region PBR may be formed by covering the surface of the trench DT with a boron-containing film and then performing heat treatment. Described specifically, the P type semiconductor region BPR can be formed by, after forming the trench DT to obtain the structure shown in FIG. 5, applying, for example, PBF (polyboron film), which is an organic film containing boron, to the surface of the trench DT and covering the surface, and carrying out heat treatment (RTA) to diffuse boron in the PBF to the surface of the trench DT. The P type semiconductor region PBR may also be formed by covering the surface of the trench DT with a boron-containing silicon film by CVD without forming PBF and carrying out heat treatment (RTA) to diffuse boron in the silicon film to the surface of the trench DT.

Next, steps similar to those described referring to FIG. 11 are performed to form a DTI structure DTI comprised of the insulating film IL0 in the trench DT. Here, the DTI structure DTI has a space SP, but it does not necessarily have the space SP as in First Embodiment. Steps subsequent thereto are performed similarly to those described referring to FIGS. 7 to 9 to obtain an image sensor shown in FIG. 14. As a result, the semiconductor device of the present modification example is completed.

The semiconductor device of the present modification example is different from that described referring to FIGS. 11 and 12 only in that the trench DT has the P type semiconductor region PBR on the respective surfaces of the epitaxial layer EP and the semiconductor substrate SB, which are the side wall and bottom surface of the trench DT. The present modification example can produce an advantage similar to that of the semiconductor device described referring to FIGS. 11 and 12.

Further in the present modification example, electrons generated at the surface of the trench DT can be prevented from transferring to a photoelectric conversion region of the pixel region PER or the peripheral circuit region CR. The trench DT is a recess formed by dry etching and electrons are generated easily from its surface damaged by dry etching. In this case, escape of electrons released from the surface of the trench DT to the photoelectric conversion region or peripheral circuit may prevent normal operation of a semiconductor element. On the other hand, in the present modification example, escape of electrons can be prevented because the P type semiconductor region PBR has a large amount of holes and the holes capture electrons. In addition, a P type impurity configuring the P type semiconductor region PBR serves as a potential barrier and can prevent diffusion of electrons released from the surface.

### Modification Example 2

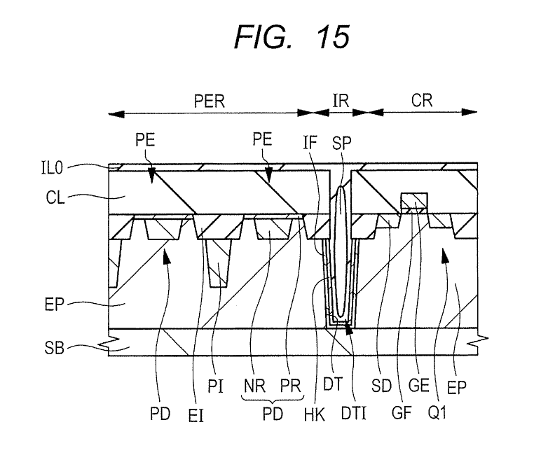

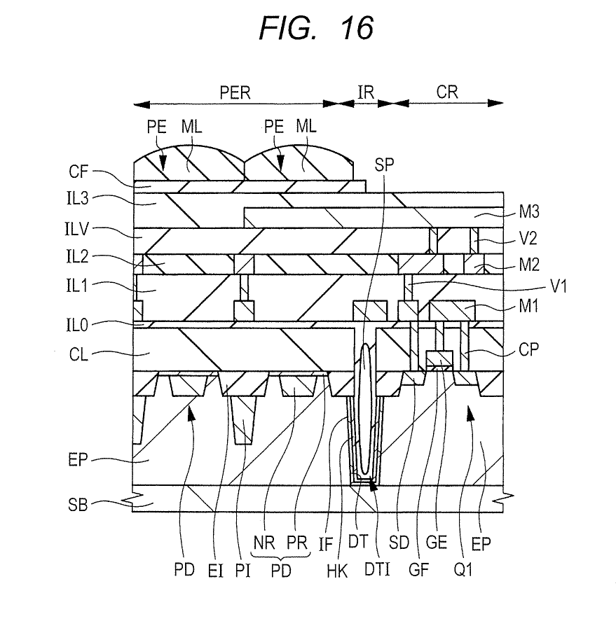

The structure and manufacturing method of a semiconductor device of Modification Example 2 of Second Embodiment will hereinafter be described referring to FIGS. 15 and 16. Here, a description will be made on formation of a high dielectric constant film between a DTI structure and a trench filled with a DTI structure. FIGS. 15 and 16 are cross-sectional views describing manufacturing steps of the semiconductor device of Modification Example 2 of the present embodiment.

First, steps similar to those described referring to FIGS. 3 to 5 are performed to form elements such as photodiode PD and transistor Q1 in the vicinity of the upper surface of the substrate and also to form an interlayer insulating film CL and a trench DT.

Next, as shown in FIG. 15, an insulating film IF which is made of a silicon oxide film and covers the surface of the trench DT is formed by oxidation method or CVD. Then, an insulating film HK that covers the surface of the trench DT is formed using, for example, CVD. The insulating film HK is a film having a dielectric constant higher than that of either of a silicon oxide film or a silicon nitride film. It is a so-called high-k film. The insulating film HK is made of a film containing, for example, Hf (hafnium). More specifically, the insulating film HK is made of, for example, hafnium oxide (HfO).

Then, an extra portion of the insulating film HK on the trench DT is removed. A step similar to that described referring to FIG. 11 is then performed to form, in the trench DT, a DTI structure DTI via the insulating films IF and HK. Here, the DTI structure DTI has therein a space SP, but as in First Embodiment, the trench DT does not necessarily have the space SP therein. By this step, the insulating films IF and HK are provided between the DTI structure DTI and the surface of the trench DT.

Steps subsequent thereto are performed similar to those described referring to FIGS. 7 to 9 to obtain an image sensor shown in FIG. 16. As a result, the semiconductor device of the present modification example is completed.

The semiconductor device of the present modification example is different from that described referring to FIGS. 11 and 12 only in that the surface of the trench DT is covered with the insulating films IF and HK. The present modification example can therefore produce an advantage similar to that of the semiconductor device referring to FIGS. 11 and 12.

In the present modification example, the respective surfaces of the epitaxial layer EP and the semiconductor substrate SB, which are side wall and bottom surface of the trench DT, have thereon the insulating film HK via the insulating film IF. Since the insulating film HK is a film having a negative fixed load, holes are induced at the surface of the epitaxial layer EP and the semiconductor substrate SB opposite to the insulating film HK via the insulating film IF.

As described above in Modification Example 1 of the present embodiment, electrons may be released from the surface of the trench DT, but due to recombination of the holes thus induced and the electrons, diffusion of the electrons into the pixel region PER and the peripheral circuit region can be prevented. This makes it possible to prevent the electrons from becoming a dark current and prevent the electrons from interfering with the normal operation of the transistor Q1.

The insulating film HK has a thickness of, for example, about 50 nm or more. The insulating film HK having such a sufficient thickness can increase negative fixed charges of the insulating film HK.

### Modification Example 3

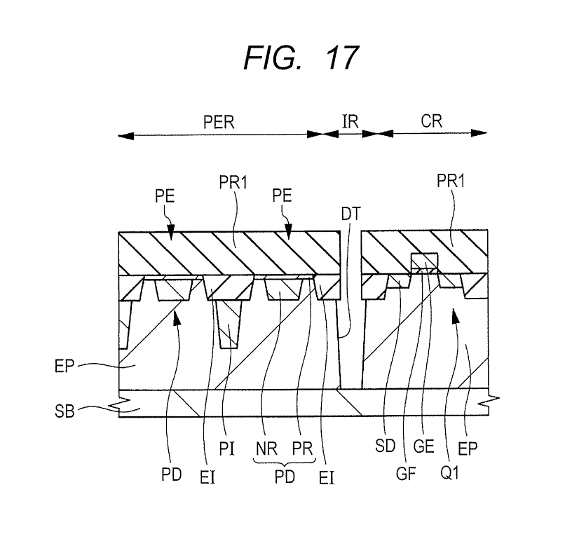

The structure and manufacturing method of a semiconductor device of Modification Example 3 of Second Embodiment will hereinafter be described referring to FIGS. 17 to 20. Here, a description will be made on formation of, after formation of a trench to be filled with a DTI structure before formation of an interlayer insulating film (contact layer), a P type semiconductor layer on the surface of the trench, followed by formation of the DTI structure by a film for forming the interlayer insulating film. FIGS. 17 to 20 are cross-sectional views describing manufacturing steps of the semiconductor device of Modification Example 3 of the present embodiment.

Here, steps similar to those described referring to FIG. 3 are performed to form elements such as photodiode PD and transistor Q1 in the vicinity of the upper surface of the substrate.

Next, as shown in FIG. 17, a resist pattern made of a photoresist film PR1 is formed on the transistor Q1 and the epitaxial layer EP. The photoresist film PR1 is a resist pattern that covers the pixel region PER and the peripheral circuit region CR and exposes only a portion of the upper surface of the element isolation region EI in the isolation region.

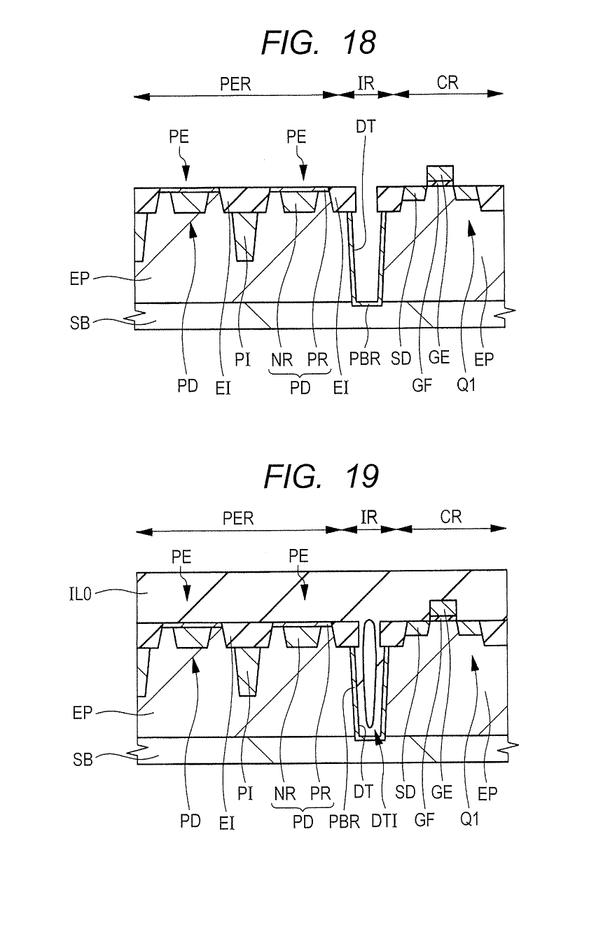

Next, as shown in FIG. 18, dry etching is performed with the photoresist film PR1 as a mask to form a trench DT. Described specifically, after opening the element isolation region EI, an opening portion extending from the bottom surface of a trench filled with the element isolation region EI to the main surface of the semiconductor substrate SB is formed. A trench DT comprised of these openings is thus formed. Then, with the photoresist film PR1 as a mask, ion implantation similar to that described referring to FIG. 13 is performed to form a P type semiconductor region PBR on the surface of the trench DT. Then, the photoresist film PR1 is removed.

Next, as shown in FIG. 19, a DTI structure DTI is formed in the trench DT by forming an insulating film IL0 on the epitaxial layer EP and in the trench DT, for example, by CVD. This method of forming the insulating film IL0 is similar to that described referring to FIG. 11. The insulating film IL0 has however a thickness greater than that of the gate electrode GE. To satisfy such a thickness, for example, the third insulating film, among films configuring the insulating film IL0, has a great thickness.

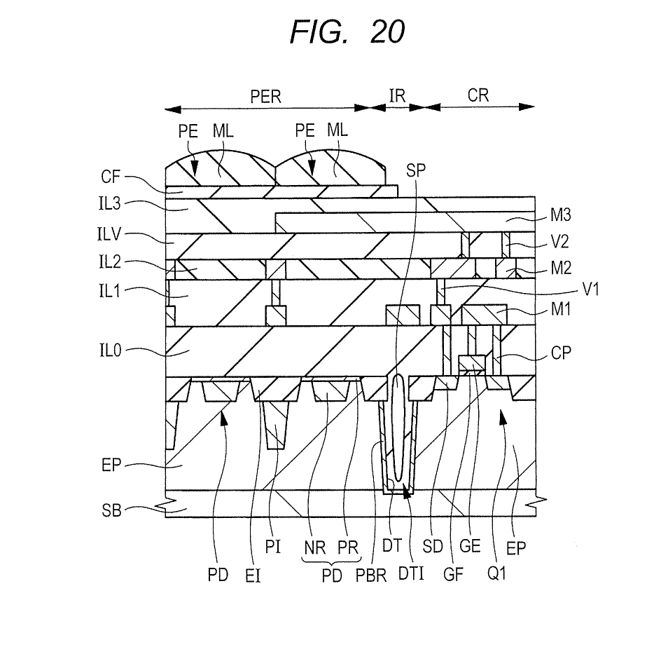

Steps subsequent thereto are performed similar to steps similar to those described referring to FIGS. 7 to 9 to form an image sensor shown in FIG. 20. As a result, the semiconductor device of the present modification example is completed.

In the present modification example, an advantage similar to that obtained by the semiconductor device described referring to FIGS. 13 and 14 can be obtained. Further, the present modification example can reduce the number of manufacturing steps of the semiconductor device by forming an interlayer insulating film of a layer (contact layer) in which a plug CP is to be formed and the DTI structure in the trench DT in one step. In the present modification example, a semiconductor device can be manufactured at a reduced cost. Further, variations in the thickness of the interlayer insulating film on the upper surface of the epitaxial layer EP can be prevented.

### Third Embodiment

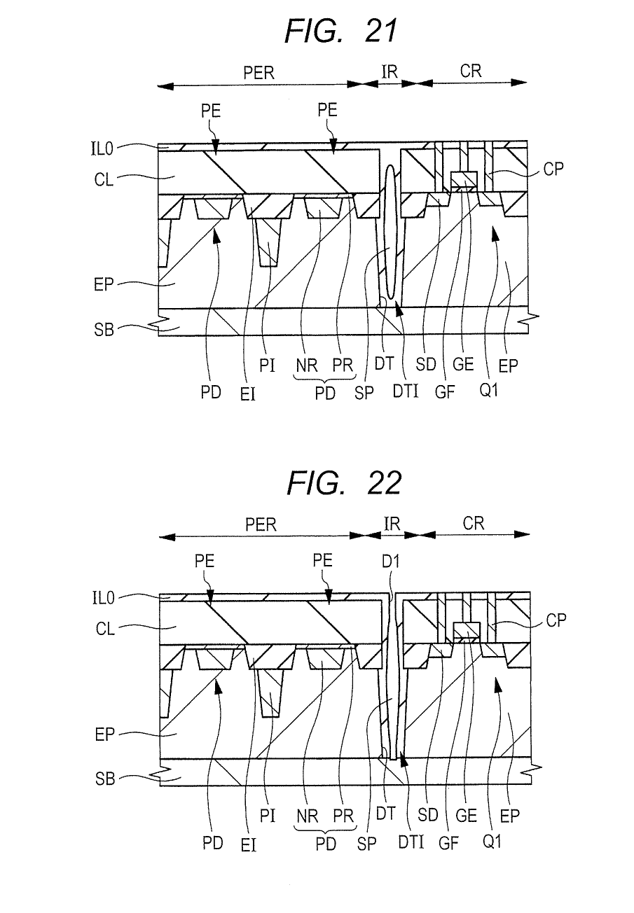

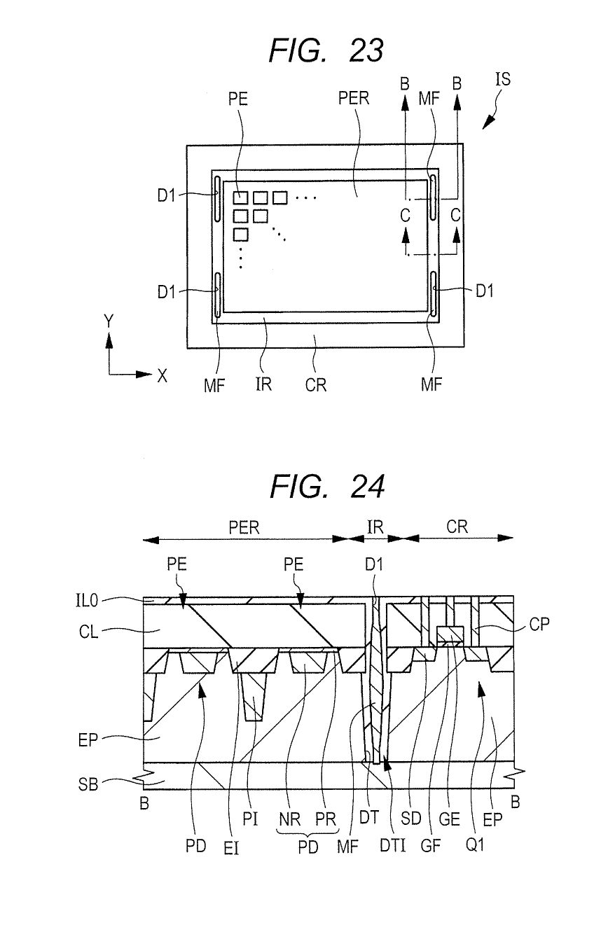

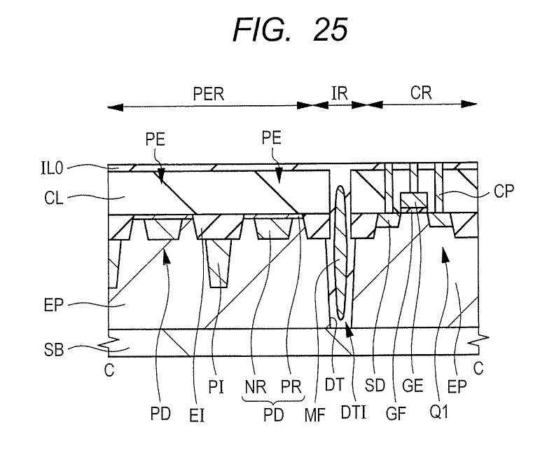

The structure and manufacturing method of a semiconductor device of Third Embodiment will hereinafter be described referring to FIGS. 21 to 26. Here, a description will be made on filling of a space in a DTI structure with a metal film. FIGS. 21, 22, and 24 to 26 are cross-sectional views describing manufacturing steps of the semiconductor device of the present embodiment. FIG. 23 is a plan view describing a manufacturing step of the semiconductor device of the present embodiment. FIG. 24 is a cross-section taken along the line B-B of FIG. 23. FIG. 25 is a cross-section taken along the line C-C of FIG. 23.

First, as shown in FIG. 21, steps similar to those described referring to FIGS. 3 to 5 and FIG. 11 are performed to form elements such as photodiode PD and transistor Q1 in the vicinity of the upper surface of the substrate and also form an interlayer insulating film CL and a trench DT. Then, steps described referring to FIGS. 7 and 8 are performed to form a plug CP that has filled a contact hole. During formation of the contact hole, it is not in contact with the space SP. This means that the space SP remains closed.

Next, as shown in FIG. 22, a trench D1 is formed in a portion of the upper surface of the insulating film IL0 in the isolation region IR by photolithography and dry etching. The trench D1 is a through-hole formed right above the space SP and extending from the upper surface of the insulating film IL0 and reaching the space SP. The space SP is thereby not closed completely at the periphery thereof. Dry etching for forming the trench D1 is continued even after the bottom portion of the trench D1 reaches the space SP so that the insulating film IL0 at the bottom portion of the space SP is also removed. From the bottom portion of the space SP, therefore, the main surface of the semiconductor substrate SB is exposed. In other words, the bottom surface of the space SP reaches the main surface of the semiconductor substrate SB.

Here, different from the isolation region IR, the space SP, and the trench DT having a closed layout in plan view, the trench D1 is not closed and it may be formed only in a portion of the isolation region IR in plan view as shown in FIG. 23 used for a later description. Here, the trench D1 is formed at a plurality of positions in the isolation region IR in plan view. The width of the trench D1 in short direction in plan view is smaller than the width of the trench DT in short direction in plan view.

Next, as shown in FIGS. 23, 24, and 25, the trench D1 and the space are filled with a metal film MF. The metal film MF is made of, for example, a titanium nitride film which is a barrier metal film, and a tungsten film deposited on the titanium nitride film. More specifically, by forming a titanium nitride film, for example, by CVD or sputtering, the upper surface of the insulating film IL0, the side wall of the trench D1, and the surface of the space SP are covered with the titanium nitride film. Then, a tungsten film is formed, for example, by CVD to cover the surface of the titanium nitride film with the tungsten film.

By this step, the space SP and the trench D1 are completely filled with the metal film MF which is a film stack of the titanium nitride film and the tungsten film. Then, the metal film MF on the interlayer insulating film CL is polished and removed, for example, by CMP to expose the upper surface of the insulating film IL0 on the interlayer insulating film CL. By this polishing step, the metal film MF remains only in the space SP and in the trench D1. The metal film MF on the insulating film IL0 may be removed not by polishing but by etching.

As shown in FIG. 23, a plurality of openings is made in the isolation region IR as the trench D1. This means that the spaces SP (refer to FIG. 21) having a closed form in plan view does not partially have the trench D1 right above. As shown in FIG. 25, however, the metal film MF is formed so as to fill the space SP having no trench D1 opened right thereabove. This means that the metal film MF having a closed structure in plan view is present in a region deeper than the surface of the DTI structure DTI shown in FIG. 23.

As shown in FIG. 25, in a region having therein no trench D1, a region having therein the space SP is not etched at the bottom portion thereof so that the bottom portion of the metal film MF does not reach the main surface of the semiconductor substrate SB and the main surface of the semiconductor substrate SB and the metal film MF have therebetween the insulating film IL0.

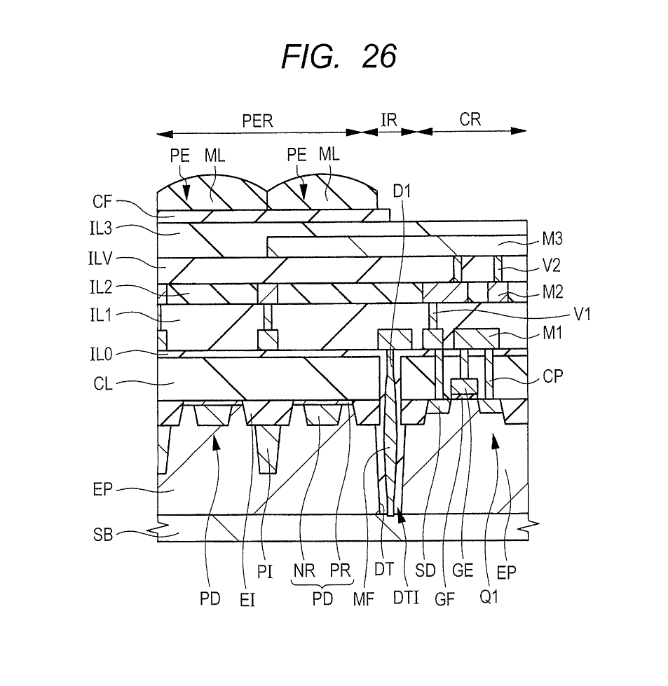

Steps subsequent thereto are performed similar to those described referring to FIG. 9 to obtain an image sensor shown in FIG. 26. As a result, the semiconductor device of the present embodiment is completed. Here, the wiring M1 is coupled to the upper surface of the metal film MF. The formation step of the contact hole and the plug CP and the formation step of the trench D1 and the metal film MF may be performed in any order.

Since a portion of the bottom surface of the metal film MF is in contact with the main surface of the semiconductor substrate SB, the metal film MF and the semiconductor substrate SB are electrically coupled to each other and have the same potential. A desired potential can therefore be applied to the semiconductor substrate SB via the wiring M1 and the metal film MF. For example, a power supply voltage Vdd is applied to the semiconductor substrate SB.

The semiconductor device of the present embodiment is different from that of First Embodiment only in that the DTI structure DTI has been filled with the metal film MF. The semiconductor device of the present embodiment can therefore produce an advantage similar to that of the semiconductor device of First Embodiment.

The metal film MF of the present embodiment does not easily transmit light compared with an insulating film such as silicon oxide film. When light is generated in the epitaxial layer EP of the peripheral circuit region CR due to operation of an element (for example, transistor Q1) in the peripheral circuit region CR, the metal film MF can block the light traveling from the epitaxial layer of the peripheral circuit region CR toward the epitaxial layer EP of the pixel region PER. Generation of a dark current can therefore be prevented.

Extra electrons generated in the epitaxial layer EP can be attracted to the semiconductor substrate SB effectively by applying a power supply voltage Vdd to the semiconductor substrate SB. Generation of crosstalk or dark current can therefore be prevented. The term “crosstalk” as used herein means that electrons generated in a deep region of the epitaxial layer EP due to light irradiated to a predetermined pixel PE transfer and are detected by a photodiode of a pixel PE other than the above-described pixel PE. Such a crosstalk causes problems such as deterioration in quality of an image available by image sensing. In the present embodiment, the voltage-applied semiconductor substrate SB is allowed to capture electrons that are bypassing below the P⁺ type semiconductor region PI and are moving toward the adjacent pixel PE.

The trench D1 may have a closed shape along the isolation region IR. In this case, it is impossible to form a wiring M1 (refer to FIG. 26) that strides over the upper surface of the metal film MF that has filled the trench D1 and is electrically coupled to another element. In the present embodiment, as shown in FIG. 23, the trench D1 does not have a closed shape along the isolation region IR but is comprised of some portions. This makes it possible to enhance the freedom of the layout of the wiring M1 configuring a first wiring layer and thereby facilitates miniaturization of a semiconductor device.

The semiconductor substrate SB may be a low-resistance N type semiconductor substrate having a resistivity of, for example, 100 mΩcm or less. In this case, the concentration of an N type impurity of the semiconductor substrate SB provided first in the manufacturing steps of the semiconductor device is set at 1×10¹⁹ atm/cm³. The N type impurity concentration of the semiconductor substrate SB is therefore higher than that of the N type semiconductor region NR. This reduces the resistance of the semiconductor substrate SB, leading to reduction in coupling resistance between the metal film MF and the semiconductor substrate SB. The semiconductor device thus obtained can be operated at less power.

### Modification Example 1

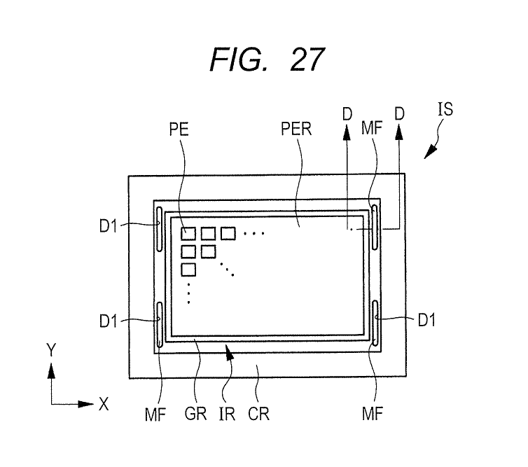

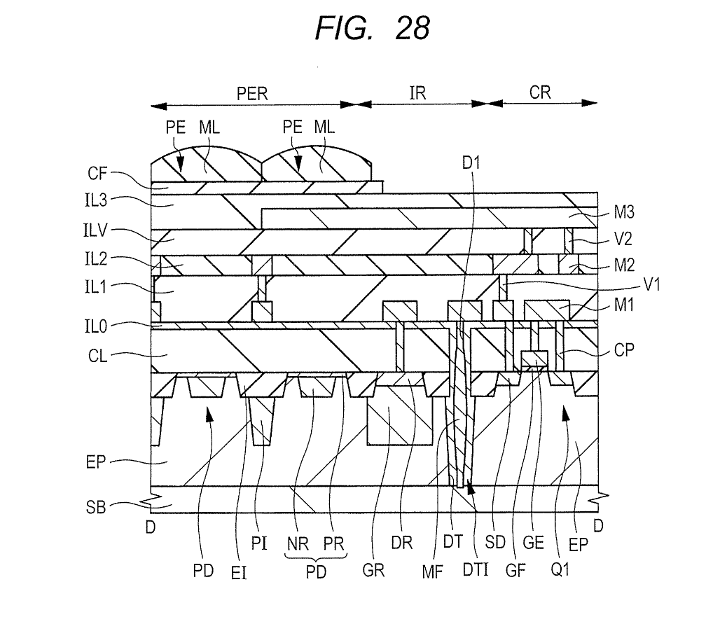

The structure and manufacturing method of a semiconductor device of Modification Example 1 of Third Embodiment will hereinafter be described referring to FIGS. 27 and 28. Here, a description will be made on the formation of an N type well in the upper surface of the epitaxial layer between the DTI structure and the pixel region in the isolation region. FIG. 27 is a plan view showing Modification Example 1 of the present embodiment. FIG. 28 is a cross-sectional view showing the semiconductor device of Modification Example 1 of the present embodiment. FIG. 28 is a cross-sectional view taken along the line D-D of FIG. 27.

As shown in FIGS. 27 and 28, a well GR, which is an N type semiconductor region, is formed in the upper surface of the epitaxial layer EP around the pixel region PER. The well GR is formed by implanting an N type impurity (for example, P (phosphorus) or As (arsenic)) by ion implantation in any timing between the step of forming an element isolation region EI and the step of forming a silicide layer on the surface of a transistor Q1.

The well GR is present in an active region located in the isolation region IR on the side of the pixel region PER relative to the trench DT. This means that the well GR is present, between two element isolation regions EI adjacent to each other, in the upper surface of the epitaxial layer EP exposed from these element isolation regions EI. The well GR extends from the upper surface of the epitaxial layer EP to the intermediate depth position of the epitaxial layer EP. The formation depth of the well GR is equal to that of, for example, the P⁺ type semiconductor region PI and is smaller than that of the trench DT.

The well GR has, in the upper surface thereof, an N type semiconductor region DR having an N type impurity concentration higher than that of the well GR and having a concentration and formation depth similar to those of the source and drain regions SD. The semiconductor region DR can be formed simultaneously with the source and drain regions SD, for example, by an ion implantation step performed for forming the source and drain regions SD. A plug CP penetrating the interlayer insulating film CL and the insulating film IL0 is coupled to the upper surface of the semiconductor region DR via a silicide layer (not shown) that covers the upper surface. To the upper surface of the plug CP, a wiring M1 is coupled.

A structure other than the above-described one is similar to that described referring to FIG. 26. The semiconductor device of First Embodiment or Second Embodiment having no metal film MF may have the well GR of the present modification example.

The well GR is a guard ring region and a power supply voltage Vdd is applied to the well GR via the wiring M1, plug CP, silicide layer (not shown), and semiconductor region DR. In the present modification example, it is possible to prevent electrons, that have generated at the surface of the trench DT on the side of the pixel region PER, that is, at the interface between the epitaxial layer EP and the DTI structure DTI, from moving to the pixel PE of the pixel region PER. This can be achieved because electrons are attracted by the well GR to which the power supply voltage Vdd has been applied. This can prevent the pixel PE from detecting dark current and noise caused by generation of electrons on the surface of the trench DT.

### Modification Example 2

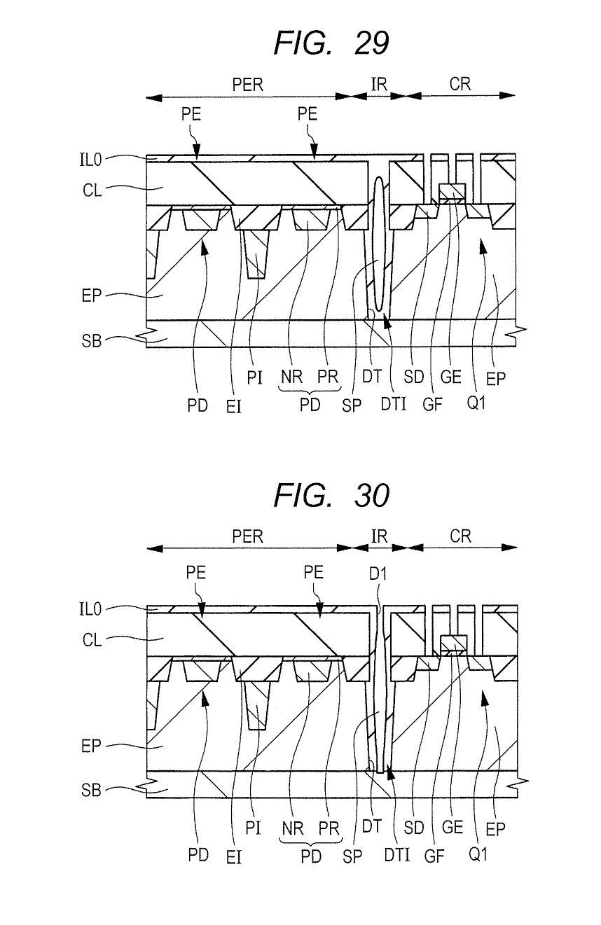

A manufacturing method of a semiconductor device of Modification Example 2 of Third Embodiment will hereinafter be described referring to FIGS. 29 to 31. Here, a description will be made on formation of a metal film with which a DTI structure is filled and a plug coupled to a transistor or the like in one step. FIGS. 29 to 31 are cross-sectional views describing the manufacturing steps of the semiconductor device of Modification Example 2 of the present embodiment.

First, steps similar to those described referring to FIGS. 3 to 5, FIG. 11, and FIG. 7 are performed successively to form a photodiode PD, a transistor Q1, an interlayer insulating film CL, a trench DT, a DTI structure DTI, a space SP, and a contact hole.

Next, as shown in FIG. 30, a step similar to that described referring to FIG. 22 is performed to form a trench D1 right above the space SP.

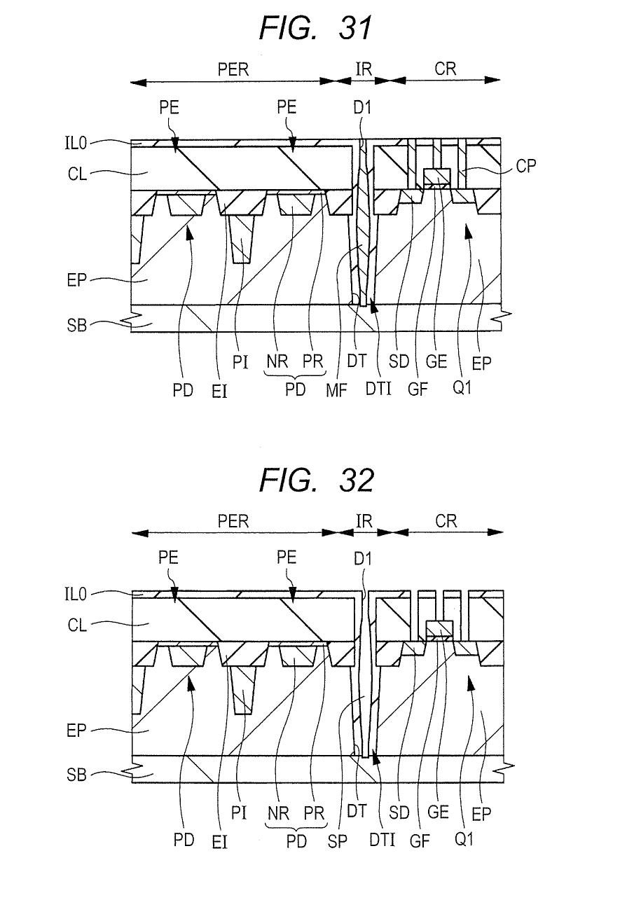

Next, as shown in FIG. 31, a titanium nitride film which is a barrier metal film and a tungsten film are formed successively to fill the space SP, trench D1, and the contact hole with them. Then, an extra portion of the metal film on the insulating film IL0 is removed by CMP or etching. By this step, the space SP and the trench D1 are filled with the metal film MF and a plug CP is formed in the contact hole. Steps subsequent thereto are performed similarly to the steps described referring to FIG. 9 to obtain an image sensor shown in FIG. 26. As a result, the semiconductor device of the present modification example is completed.

In the present modification example, the number of manufacturing steps of the semiconductor device can be reduced by forming the metal film MF and the plug CP in one step. The semiconductor device can therefore be manufactured at less cost. In addition, variation in the thickness of the interlayer insulating film on the upper surface of the epitaxial layer EP can be prevented.

### Modification Example 3

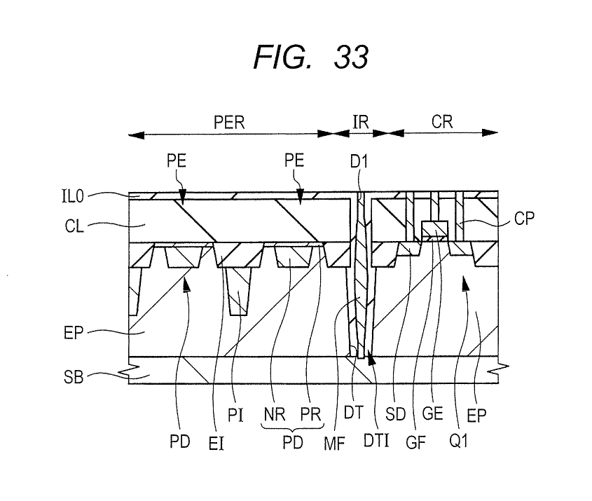

A manufacturing method of a semiconductor device of Modification Example 3 of Third Embodiment will hereinafter be described referring to FIGS. 32 and 33. Here, a description will be made on the formation of a contact hole and a trench right above a space in a DTI structure in one step and formation of a plug and a metal film with which a DTI structure is filled in one step. FIGS. 32 and 33 are cross-sectional views describing manufacturing steps of the semiconductor device of Modification Example 3 of the present embodiment.

First, as shown in FIG. 29, steps similar to those described referring to FIGS. 3 to 5 and FIG. 11 are performed successively to form a photodiode PD, a transistor Q1, an interlayer insulating film CL, a trench DT, a DTI structure DTI, and a space SP.

Next, as shown in FIG. 32, a contact hole right above the trench D1, the transistor Q1, and the like is formed using photolithography and etching. The contact hole formed here has a structure similar to that of the contact hole described in First Embodiment. The trench D1 formed here has a structure similar to that of the trench D1 described in Second Embodiment. One of the characteristics of the present modification example is formation of the trench D1 and the contact hole by one etching step.

Next, as shown in FIG. 33, a metal film MF in the space SP and the trench D1 and a plug CP in the contact hole are formed by performing a step similar to that described referring to FIG. 31. Steps subsequent thereto are performed similarly to that described referring to FIG. 9 to obtain an image sensor shown in FIG. 26. As a result, the semiconductor device of the present modification example is completed.

In the present modification example, the number of manufacturing steps of a semiconductor device can be reduced by forming the trench D1 and the contact hole in one step and forming the metal film MF and the plug CP in one step. The semiconductor device can therefore be manufactured at a less cost. In addition, variations in the thickness of the interlayer insulating film on the upper surface of the epitaxial layer can be prevented.

The invention made by the present inventors has been described specifically based on some embodiments. It is needless to say that the invention is not limited to or by these embodiments and can be changed in various ways without departing from the gist of the invention.

What is claimed is:

1. A semiconductor device having a solid state image sensor equipped with a pixel including a photodiode, comprising:
a semiconductor substrate having an N conductivity type;
a semiconductor layer formed over the semiconductor substrate and having a P conductivity type;
a plurality of the photodiodes formed in an upper surface of the semiconductor layer in a first region;
a transistor formed over the semiconductor layer in a second region surrounding the first region in plan view;
an element isolation region buried in a first trench formed in the upper surface of the semiconductor layer between the photodiodes; and
an isolation portion including a first insulating film formed in the semiconductor layer in a third region between the first region and the second region and formed in a second trench deeper than the first trench.

2. The semiconductor device according to claim 1,
wherein the second trench and the isolation portion reach the main surface of the semiconductor substrate.

3. The semiconductor device according to claim 1,
wherein the thickness of the semiconductor layer in a direction orthogonal to the main surface of the semiconductor substrate is more than 5 μm.

4. The semiconductor device according to claim 1,
wherein in the second trench, the first insulating film has therein a space.

5. The semiconductor device according to claim 1,
wherein in the second trench, the first insulating film has been filled with a metal film.

6. The semiconductor device according to claim 5, further comprising:
a wiring formed over the transistor via a second insulating film; and
a coupling portion penetrating the second insulating film,
wherein the wiring is electrically coupled to the semiconductor substrate via the coupling portion and the metal film.

7. The semiconductor device according to claim 6,
wherein the photodiode includes an N type semiconductor region formed in the semiconductor layer, and
wherein the semiconductor substrate has an N type impurity concentration greater than that of the N type semiconductor region.

8. The semiconductor device according to claim 1, further comprising:
a first semiconductor region formed over the surface of the second trench and having a P conductivity type.

9. The semiconductor device according to claim 1, further comprising a second semiconductor region formed over the bottom surface of the first trench and having a P conductivity type,
wherein the second semiconductor region reaches an intermediate depth position of the semiconductor layer.

10. The semiconductor device according to claim 1, further comprising a third insulating film formed between the second trench and the isolation portion,
wherein the third insulating film has a dielectric constant higher than that of silicon nitride.

11. A method of manufacturing a semiconductor device having a solid state image sensor equipped with a pixel including a photodiode, comprising the steps of:
(a) providing a semiconductor substrate having an N conductivity type;
(b) forming an epitaxial layer having a P conductivity type over the semiconductor substrate;
(c) forming a plurality of photodiodes in an upper surface of the epitaxial layer in a first region;
(d) forming a transistor over the upper surface of the epitaxial layer in a second region surrounding the first region in plan view;
(e) forming an element isolation region that isolates the photodiodes from each other in a first trench formed in the upper surface of the epitaxial layer;
(f) forming a second trench deeper than the first trench in the upper surface of the epitaxial layer in a third region between the first region and the second region; and
(g) filling the second trench with a first insulating film and thereby forming an isolation portion including the first insulating film.

12. The method of manufacturing a semiconductor device according to claim 11,
wherein in the step (f), the second trench penetrates the epitaxial layer.

13. The method of manufacturing a semiconductor device according to claim 11, further comprising:
(h) forming a P type semiconductor region in the upper surface of the epitaxial layer between the photodiodes adjacent to each other by ion implantation,
wherein a bottom portion of the P type semiconductor region is separated from a bottom surface of the epitaxial layer.

14. The method of manufacturing a semiconductor device according to claim 11,
wherein the thickness of the epitaxial layer in a direction orthogonal to the main surface of the semiconductor substrate is more than 5 μm.

15. The method of manufacturing a semiconductor device according to claim 11,
wherein in the step (f), the number of the second trench formed is four and they extend along four sides of the first region having a rectangular shape in plan view, and
wherein the second trench extending in a first direction is separated from another second trench extending in a second direction orthogonal to the first direction.
